(19) United States
(12) Patent Application Publication
(10) Pub. No.: US 2022/0021826 A1
(43) Pub. Date: Jan. 20, 2022

(54) IMAGING DEVICE AND ELECTRONIC APPARATUS

(71) Applicant: SONY SEMICONDUCTOR SOLUTIONS CORPORATION, Kanagawa (JP)

(72) Inventor: Hirokazu EJIRI, Kanagawa (JP)

(73) Assignee: SONY SEMICONDUCTOR SOLUTIONS CORPORATION, Kanagawa (JP)

(21) Appl. No.: 17/298,885

(22) PCT Filed: Dec. 9, 2019
(86) PCT No.: PCT/JP2019/048072

§ 371 Date: Jun. 1, 2021

(30) Foreign Application Priority Data
Dec. 10, 2018 (JP) 2018-230835

(51) Int. Cl. H04N 5/357; H04N 5/3745; H04N 5/378; H04N 5/369; H01L 27/146

(52) U.S. Cl. CPC H04N 5/357; H04N 5/37455; H04N 5/37457; H04N 5/378; H01L 27/14641; H01L 27/14634; H01L 27/14689; H01L 27/1469; H01L 27/14603; H04N 5/379

(57) ABSTRACT

An imaging device includes a first substrate including at least one sensor portion that converts light into electric charge, and a second substrate including a first portion of a readout circuit having at least one first transistor. The readout circuit outputs a pixel signal based on the electric charge. The imaging device includes a third substrate including a logic circuit that performs processing on the pixel signal. The first substrate, the second substrate, and the third substrate are stacked in that order.

### CROSS REFERENCE TO RELATED APPLICATIONS

This application claims the benefit of Japanese Priority Patent Application JP 2018-230835 filed Dec. 10, 2018, the entire contents of which are incorporated herein by reference.

### TECHNICAL FIELD

The present disclosure relates to an imaging device and an electronic apparatus using such an imaging device.

### BACKGROUND ART

One example of a circuit reading a signal from a pixel in an imaging device is an analog-to-digital conversion circuit (an analog-to-digital (A/D) converter) including a comparator and a digital circuit disposed in a stage subsequent to the comparator (for example, refer to PTL 1). The A/D converter has high area efficiency.

PTL 1 discloses an imaging device including A/D converters, one of which is provided for each of pixels.

### CITATION LIST

### Patent Literature

PTL 1: International Publication No. WO 2016/136448

### SUMMARY

### Technical Problem

In such an imaging device, noise reduction is desired.

It is desirable to provide an imaging device and an electronic apparatus that make it possible to reduce noise.

### Solution to Problem

An imaging device according to an embodiment of the present disclosure includes a stacking structure including a first substrate, a second substrate, and a third substrate that are stacked in order. The first substrate includes a sensor pixel that performs photoelectric conversion and outputs a signal charge. The second substrate includes a first signal processing circuit that is included in a readout circuit and includes a first analog transistor. The readout circuit outputs a pixel signal on the basis of the signal charge. The third substrate includes a logic circuit that performs processing on the pixel signal. An imaging device according to an embodiment of the present disclosure includes a first substrate including at least one sensor portion that converts light into electric charge, and a second substrate including a first portion of a readout circuit including at least one first transistor. The readout circuit outputs a pixel signal based on the electric charge. The imaging device includes a third substrate including a logic circuit that performs processing on the pixel signal. The first substrate, the second substrate, and the third substrate are stacked in that order. The first substrate further includes a floating diffusion that accumulates the electric charge, and the at least one first transistor includes an amplification transistor including a gate electrode coupled to the floating diffusion. The at least one sensor portion comprises a plurality of sensor portions, and the readout circuit includes an analog-to-digital conversion circuit for each of the plurality of sensor portions. The readout circuit includes a first part of an analog-to-digital conversion circuit including a comparison circuit, and the at least one first transistor is included in the comparison circuit. The at least one sensor portion comprises a plurality of sensor portions provided in rows and columns, and the readout circuit includes an analog-to-digital conversion circuit for each of the columns. The readout circuit includes a vertical signal line, and the at least one first transistor includes a load transistor coupled to the vertical signal line. The readout circuit includes a sample-and-hold circuit, and the at least one first transistor includes an input transistor included in the sample-and-hold circuit. The at least one first transistor includes a channel region provided in a semiconductor region of the second substrate, a gate insulation film provided on the channel region, a gate electrode provided on the gate insulation film, a source region provided at a position adjacent to the channel region in the semiconductor region of the second substrate, a drain region provided in the semiconductor region of the second substrate at a position adjacent to the channel region on a side of the channel region opposite to the source region, a first metal layer provided to cover a front surface of the gate electrode, a second metal layer provided to cover a front surface of the source region, and a third metal layer provided to cover a front surface of the drain region. The third substrate includes a second portion of the readout circuit coupled to the first portion of the readout circuit, and the second portion of the readout circuit includes a second transistor. The at least one first transistor includes an NMOS transistor and/or a PMOS transistor, and the at least one first transistor receives and outputs an analog signal based on the electric charge, and the second transistor receives and outputs a digital signal based on the analog signal. The at least one sensor portion includes a plurality of sensor portions that share the at least one first transistor. The at least one sensor portion includes a photodiode and a transfer transistor. The readout circuit includes one or more of an amplification transistor, a reset transistor, and a select transistor. The first portion of the readout circuit includes a first portion of an analog-to-digital conversion circuit, and the logic circuit includes a second portion of the analog-to-digital conversion circuit. The first portion of the analog-to-digital conversion circuit receives an analog signal based on the electric charge, and the second portion of the analog-to-digital conversion circuit outputs a digital signal based on the analog signal. The at least one sensor portion includes a plurality of sensor portions that share the first portion and the second portion of the analog-to-digital conversion circuit. The at least one sensor portion comprises a plurality of sensor portions, and the first substrate includes the plurality of sensor portions and includes an isolation region that separates the plurality of sensor portions. The at least one sensor portion includes a plurality of sensor portions, and the first substrate includes the plurality of sensor portions and the readout circuit is electrically coupled to the plurality of sensor portions. The at least one sensor portion comprises a plurality of sensor portions, and the first substrate includes a floating diffusion for each of the plurality of sensor portions. The at least one sensor portion comprises a plurality of sensor portions, and the first substrate includes the plurality of sensor portions and includes a floating diffusion shared by the plurality of sensor portions.

An electronic apparatus according to an embodiment of the present disclosure includes an optical system, an imaging device, and a signal processing circuit. The imaging device includes a stacking structure including a first substrate, a second substrate, and a third substrate that are stacked in order. The first substrate includes a sensor pixel that performs photoelectric conversion and outputs a signal charge. The second substrate includes a first signal processing circuit that is included in a readout circuit and includes a first analog transistor. The readout circuit outputs a pixel signal on the basis of the signal charge. The third substrate includes a logic circuit that performs processing on the pixel signal. According to an embodiment of the present disclosure, an electronic apparatus includes an optical system, an imaging device, and a signal processing circuit. The imaging device a first substrate including at least one sensor portion that converts light into electric charge, and a second substrate including a first portion of a readout circuit and including at least one first transistor. The readout circuit outputs a pixel signal based on the electric charge. The imaging device includes a third substrate including a logic circuit that performs processing on the pixel signal. The first substrate, the second substrate, and the third substrate are stacked in that order.

In the imaging device and the electronic apparatus according to the embodiments of the present disclosure, the first signal processing circuit including the first analog transistor is provided in the second substrate, and the first signal processing circuit is included in the readout circuit that reads a pixel signal from the sensor pixel.

### BRIEF DESCRIPTION OF DRAWINGS

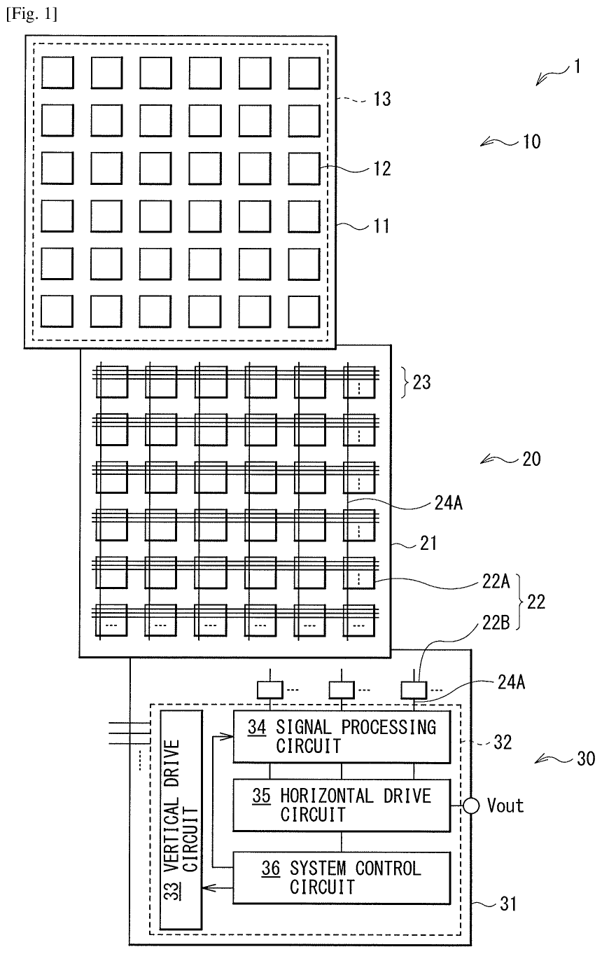

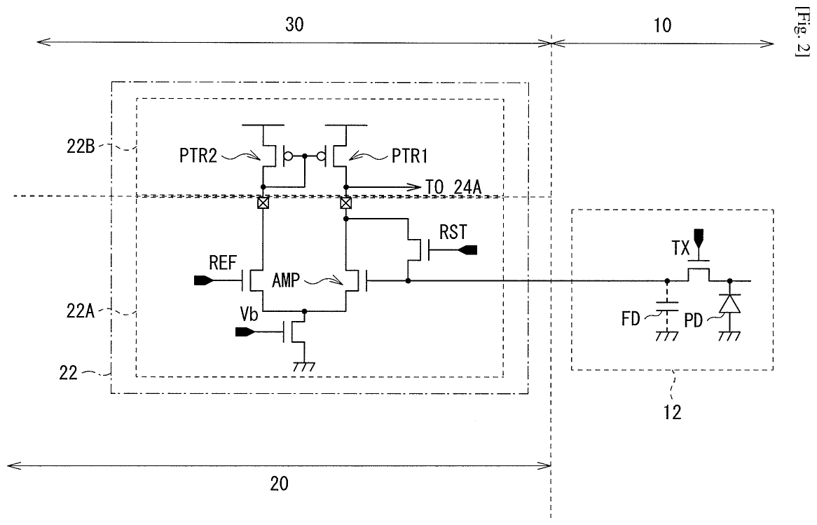

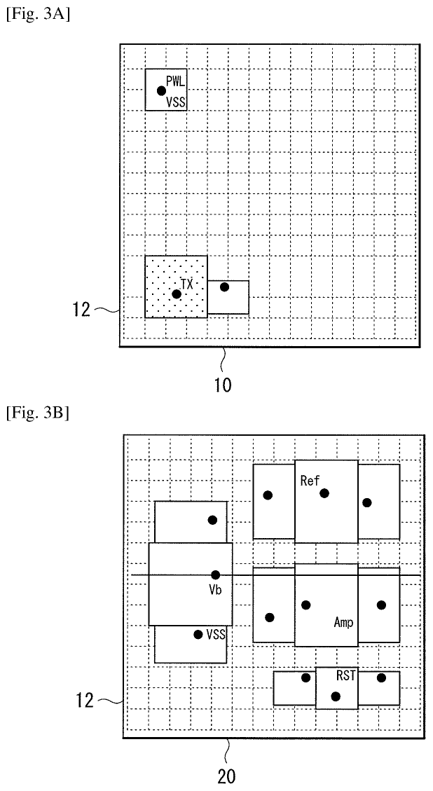

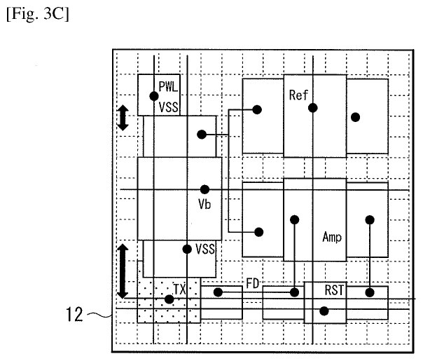

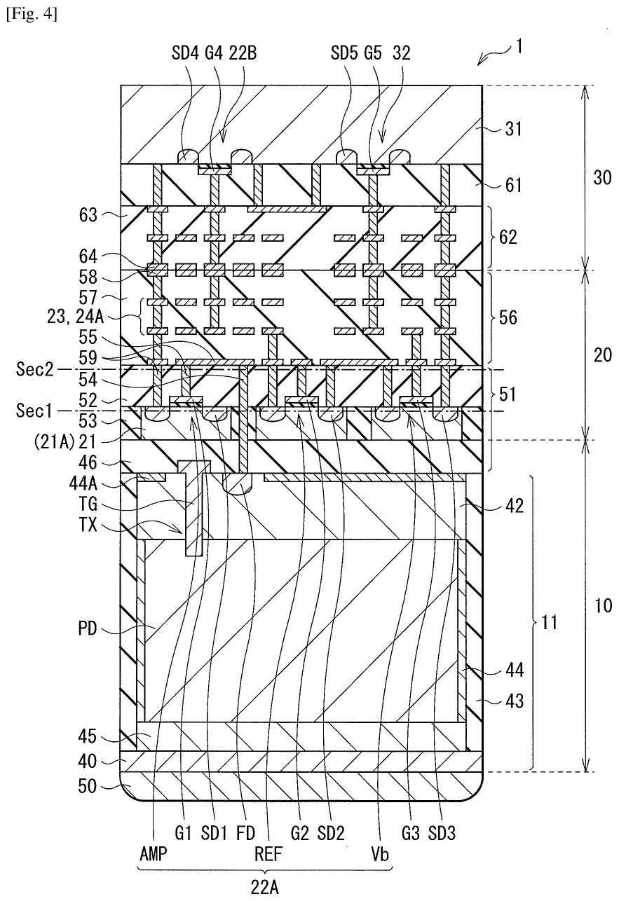

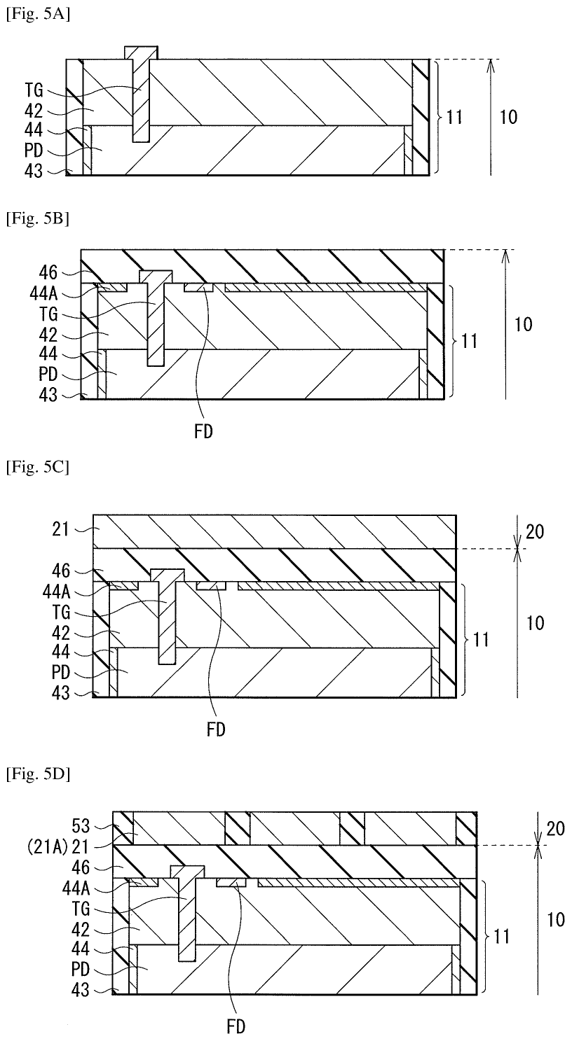

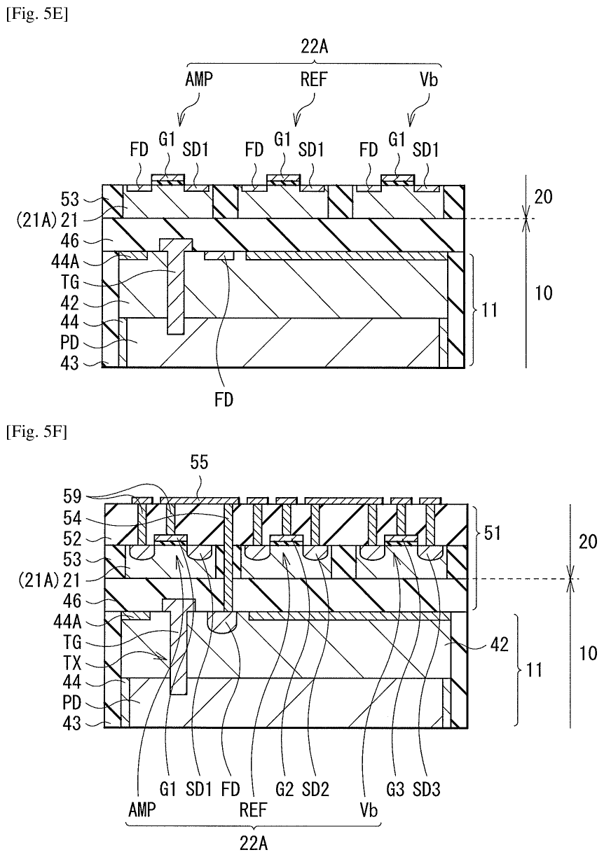

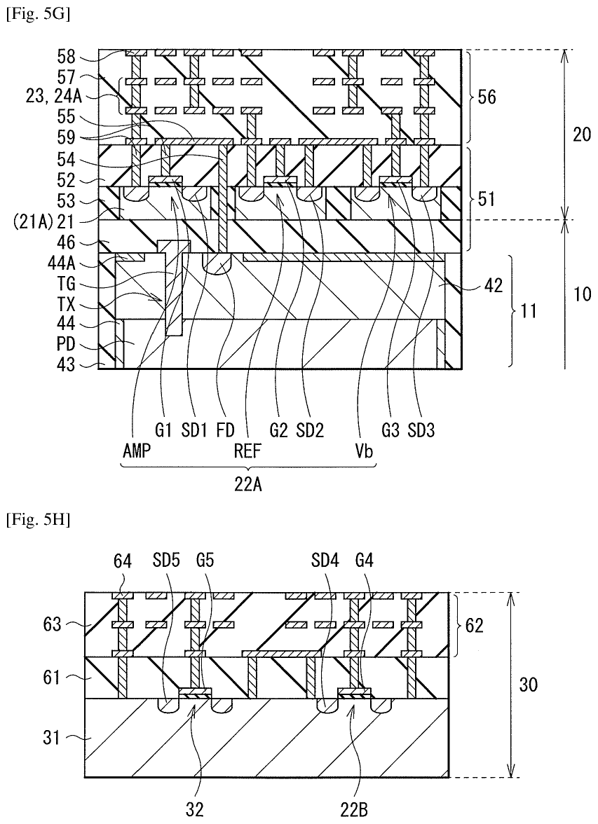

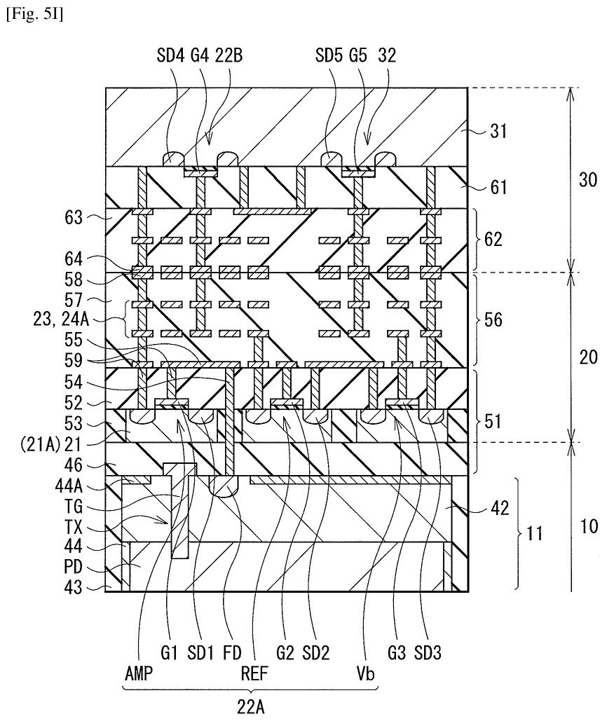

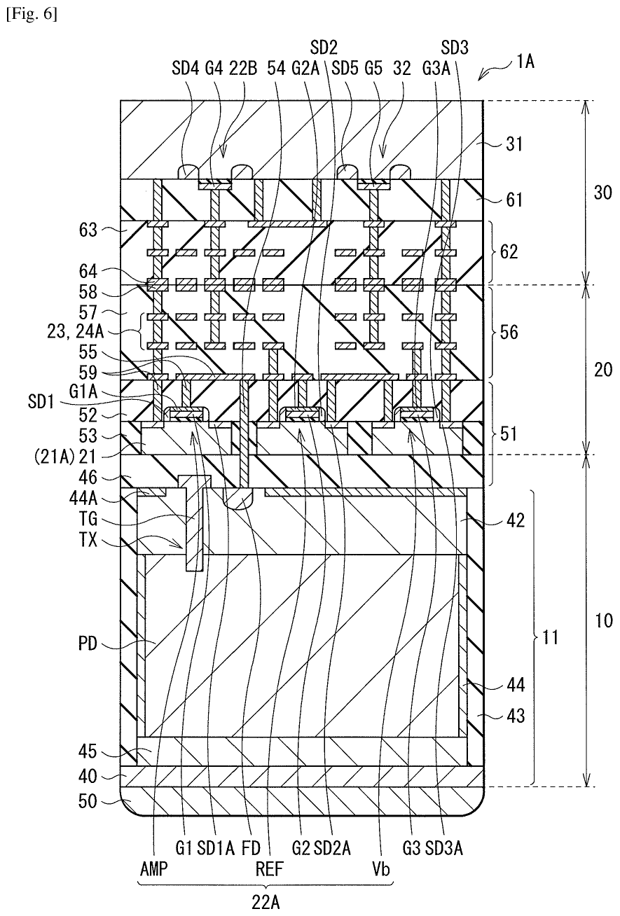

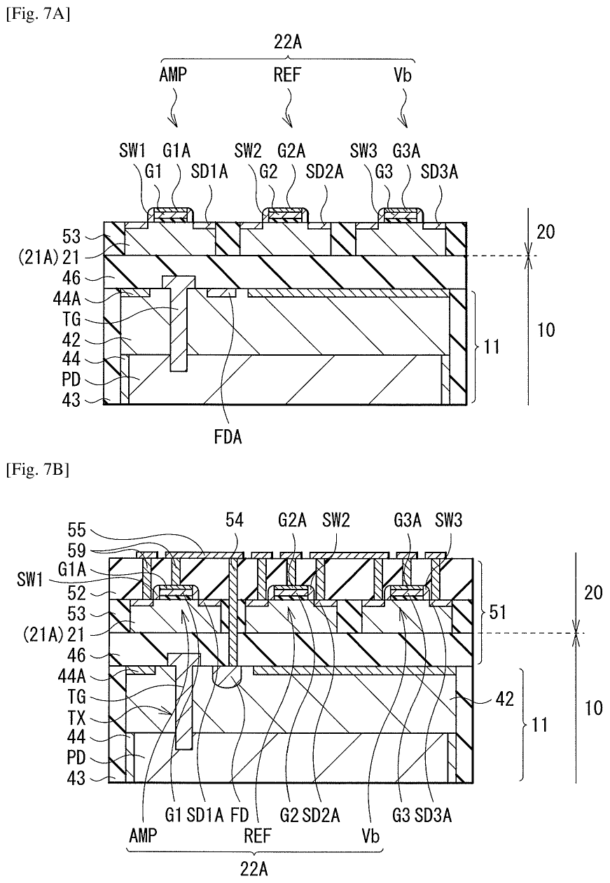

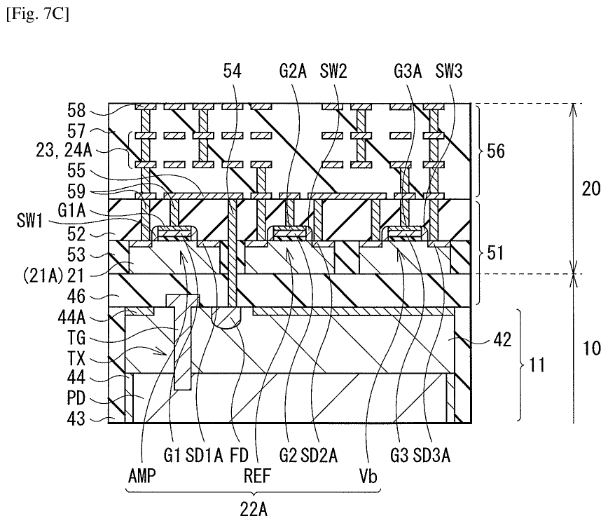

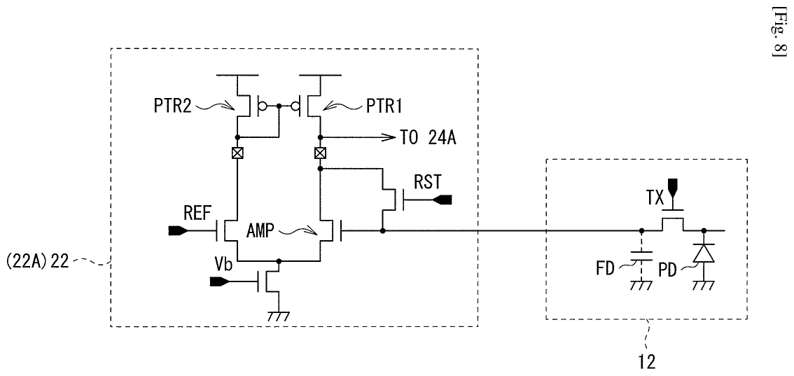

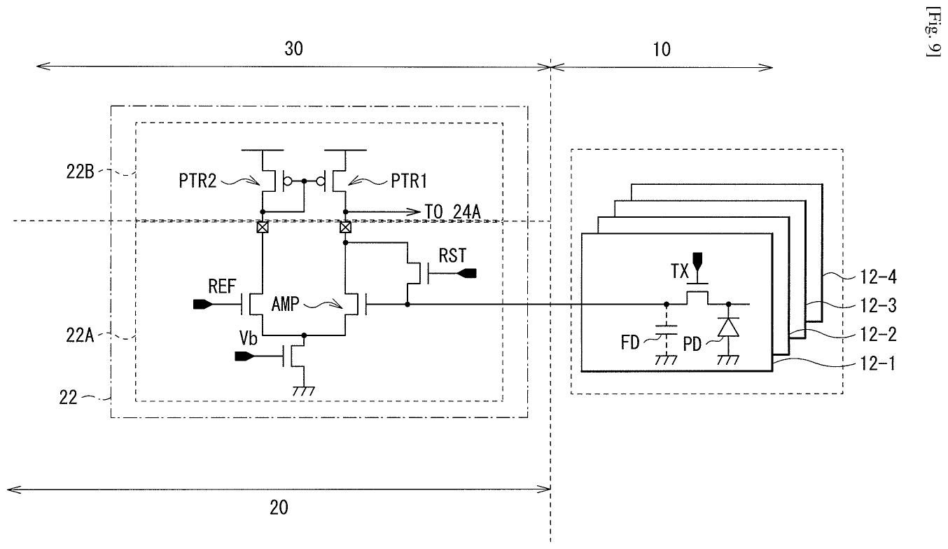

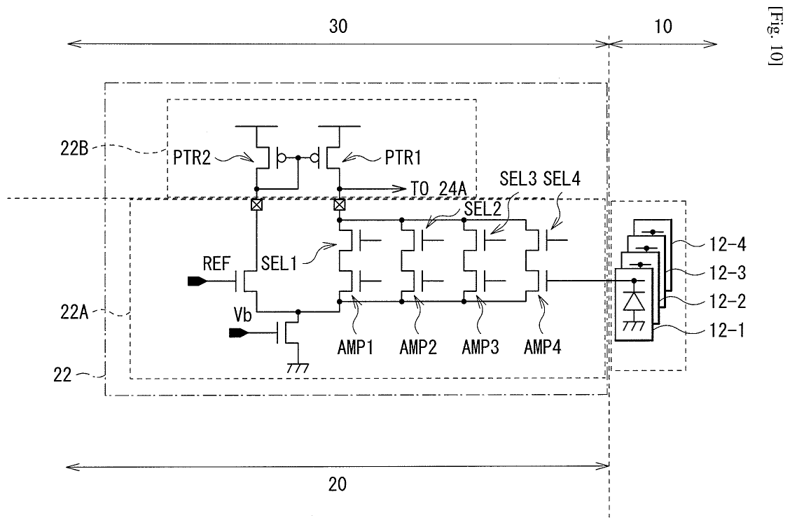

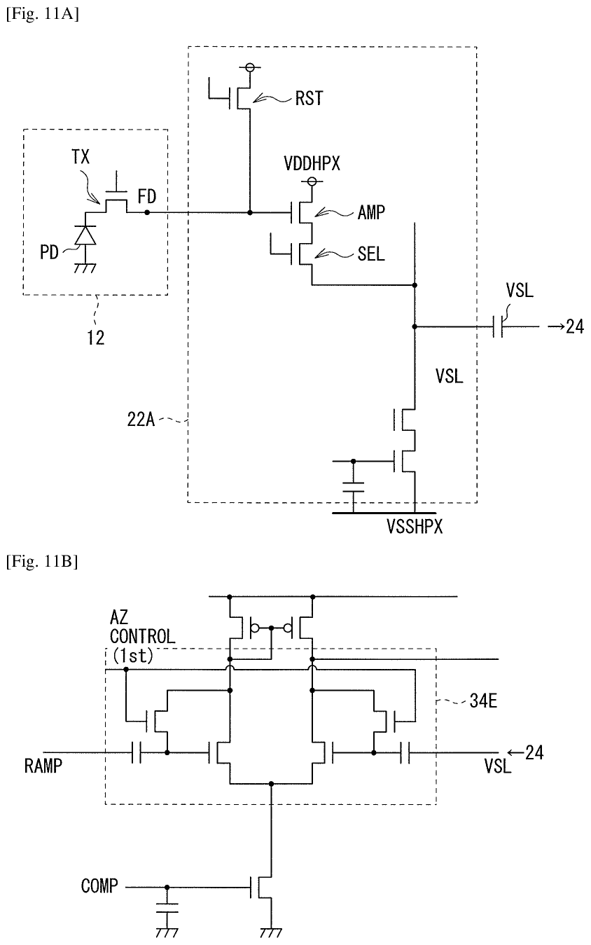

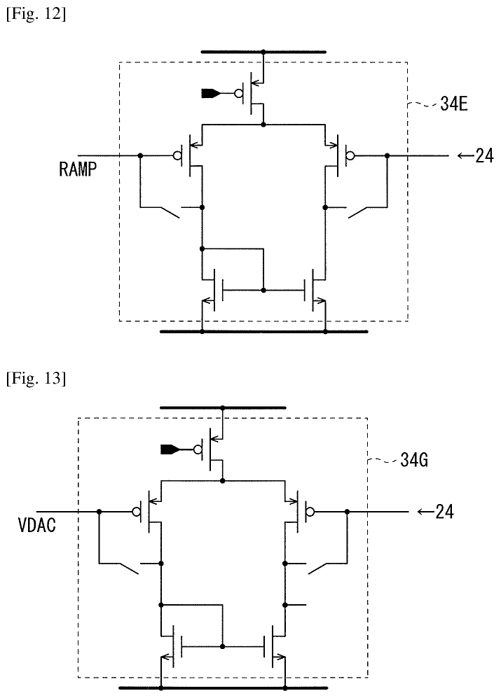

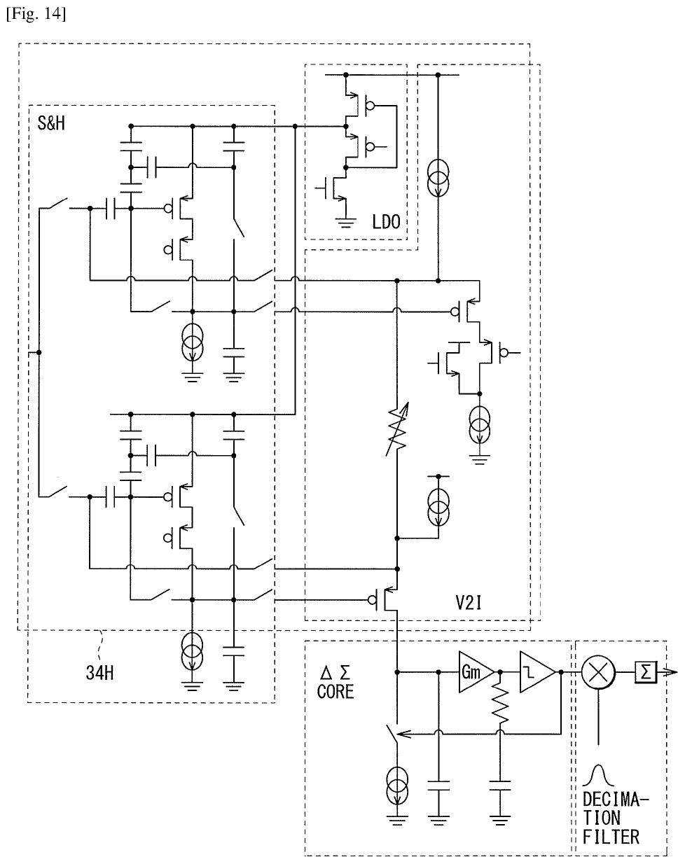

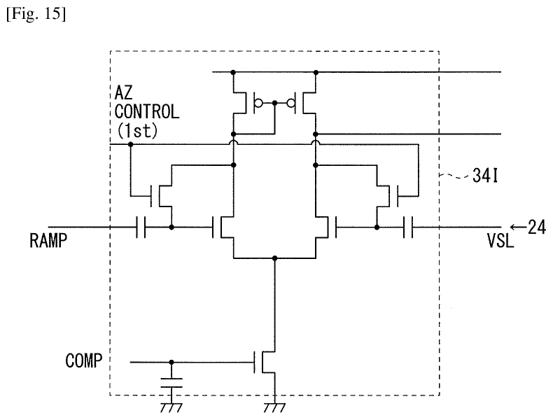

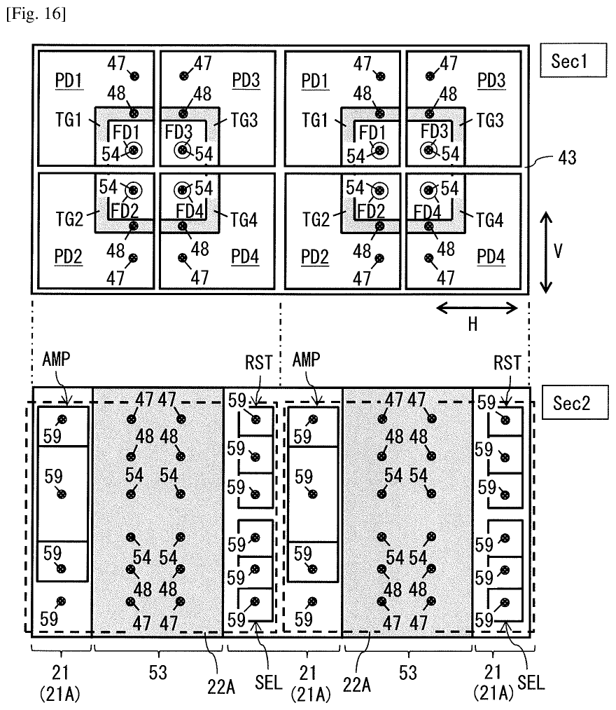

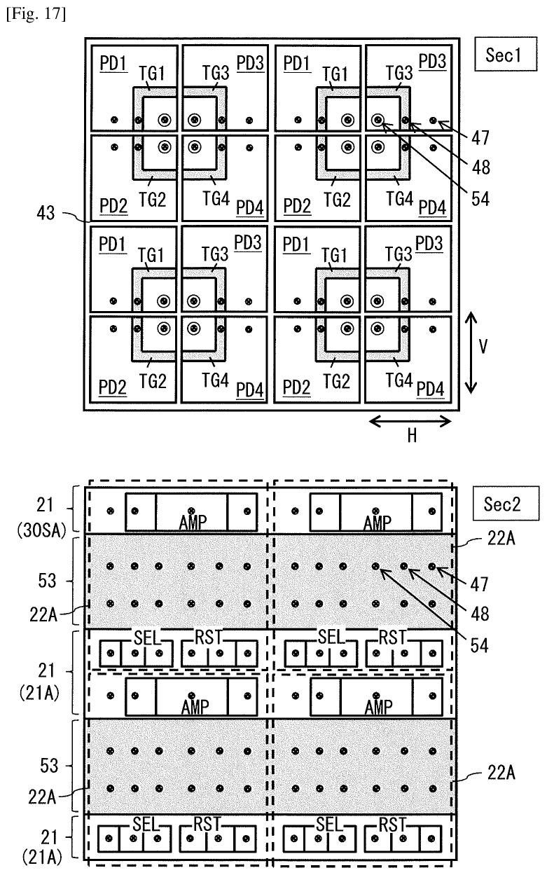

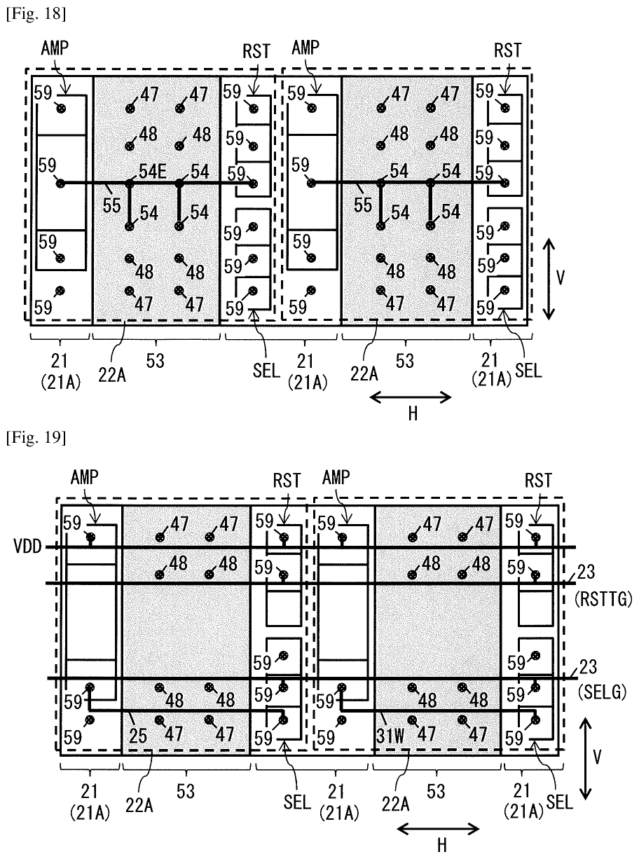

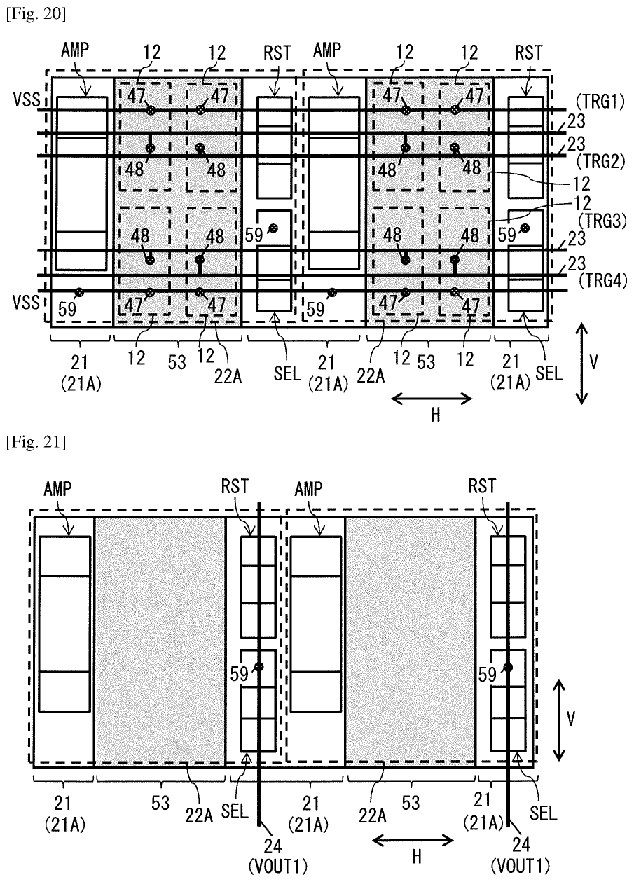

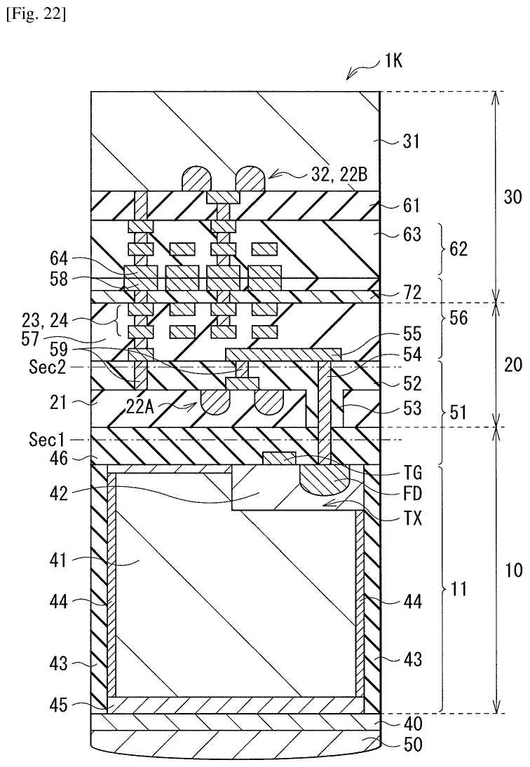

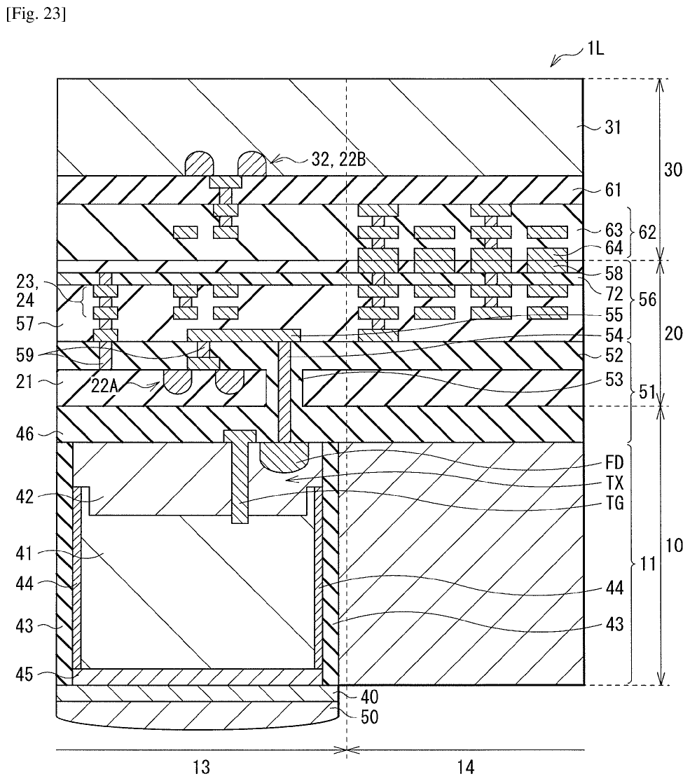

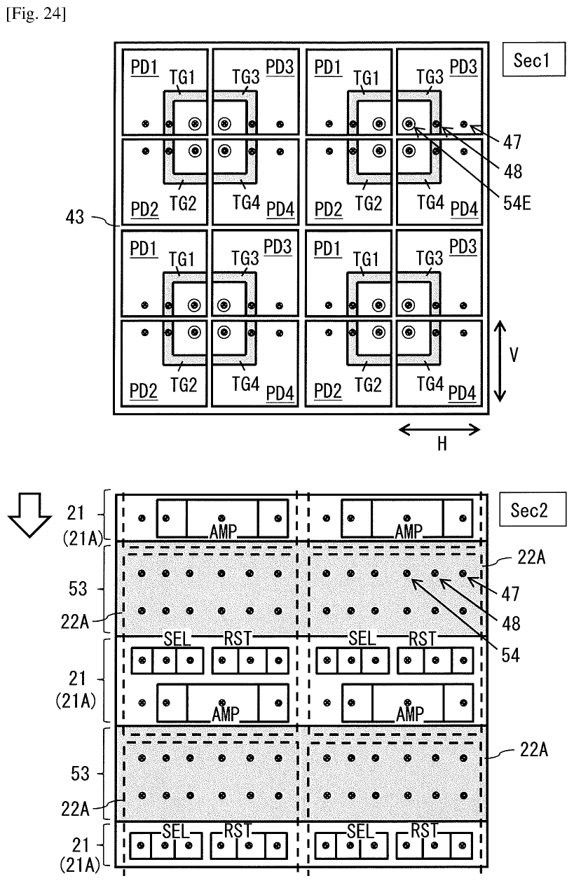

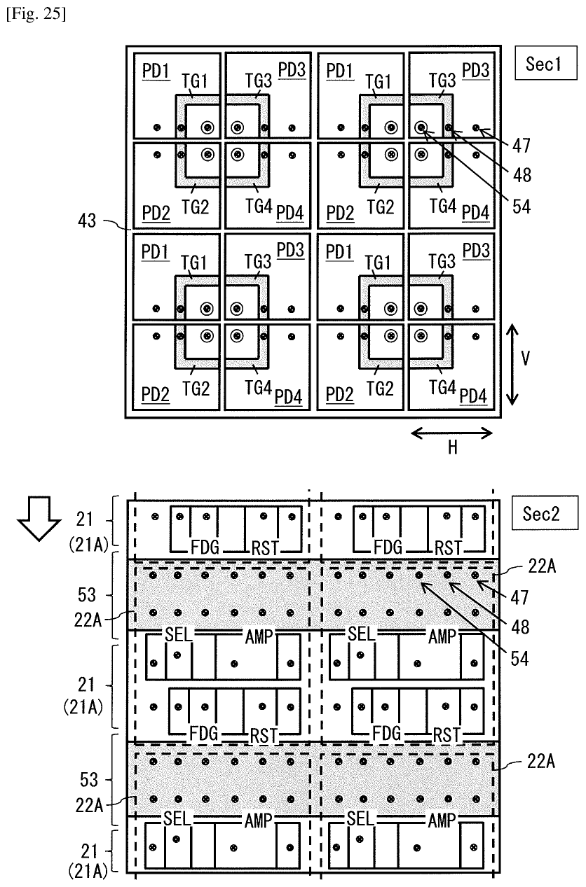

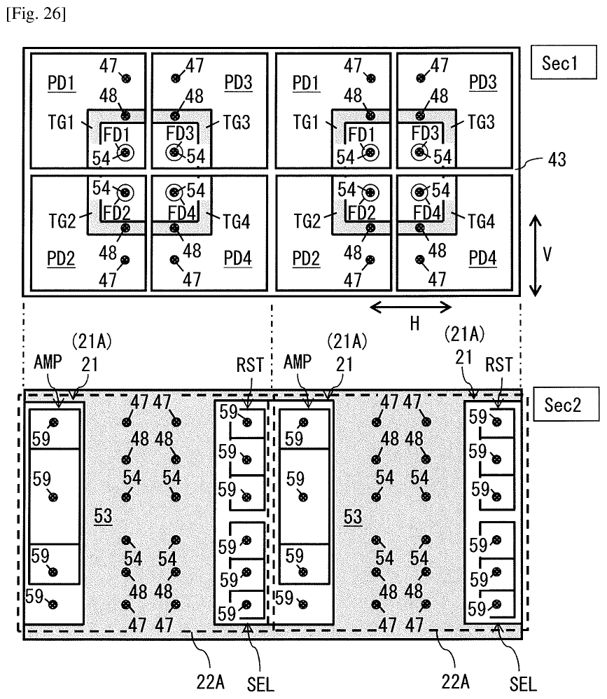

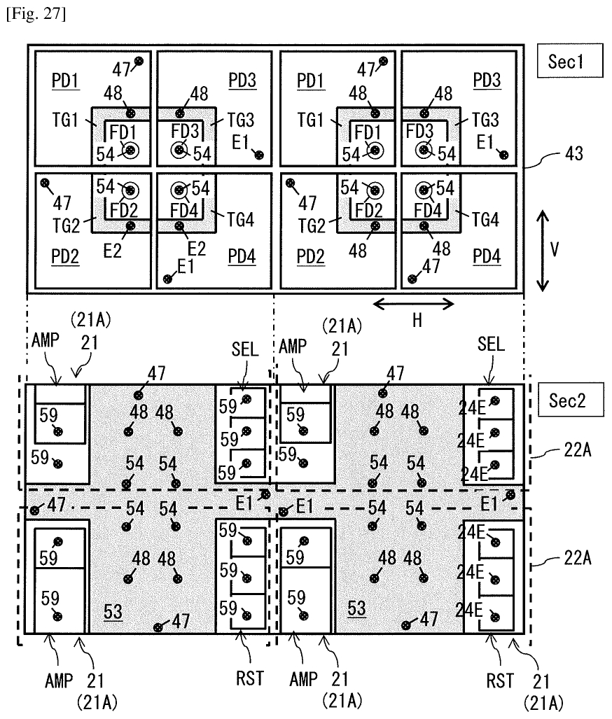

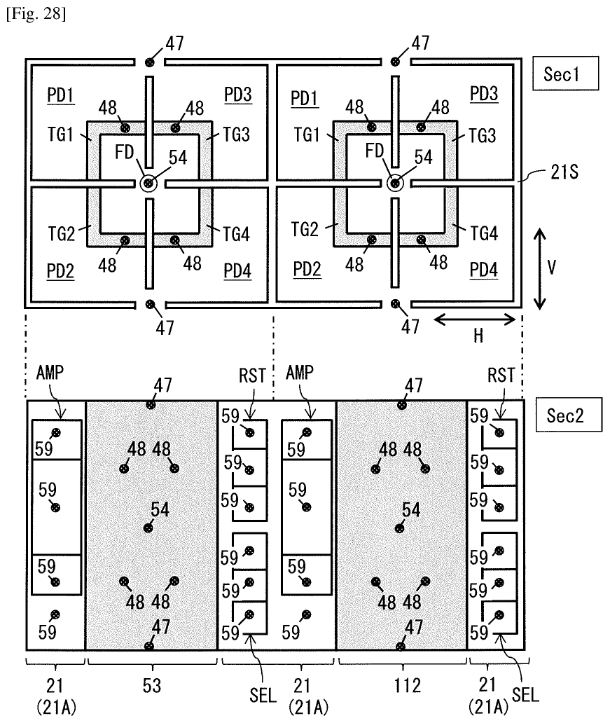

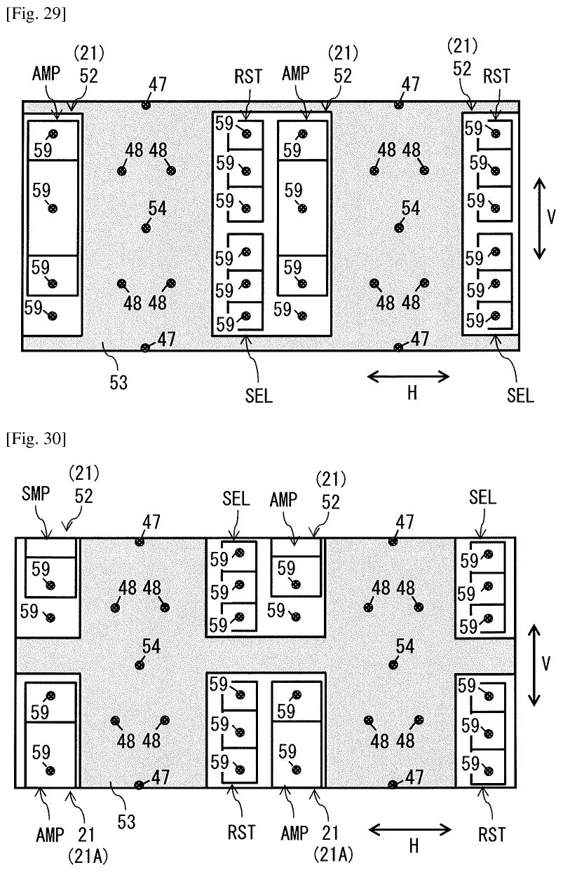

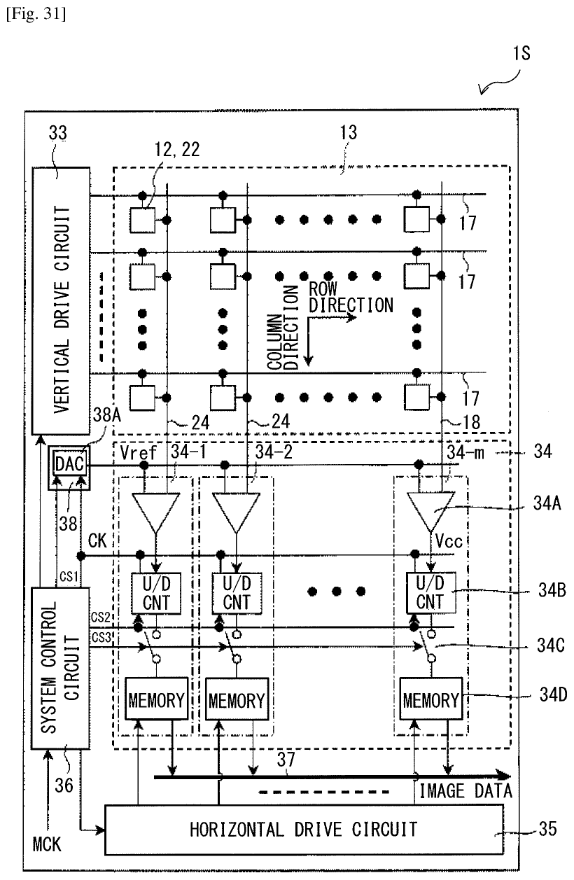

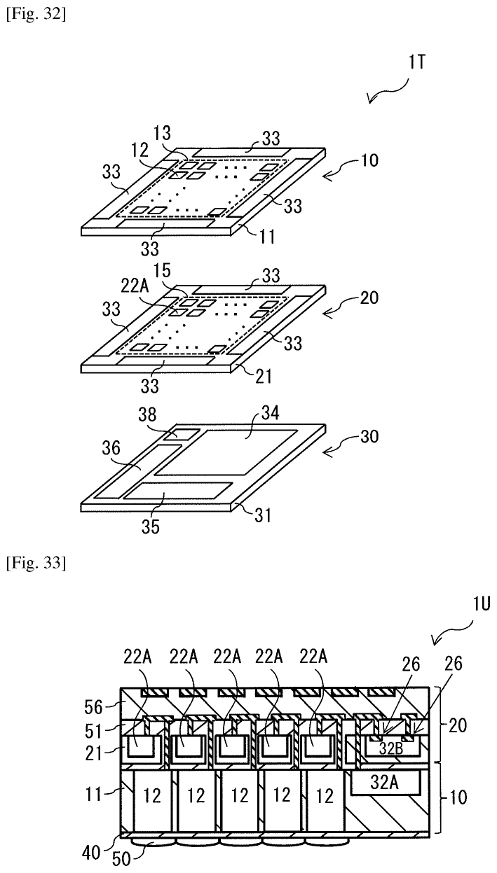

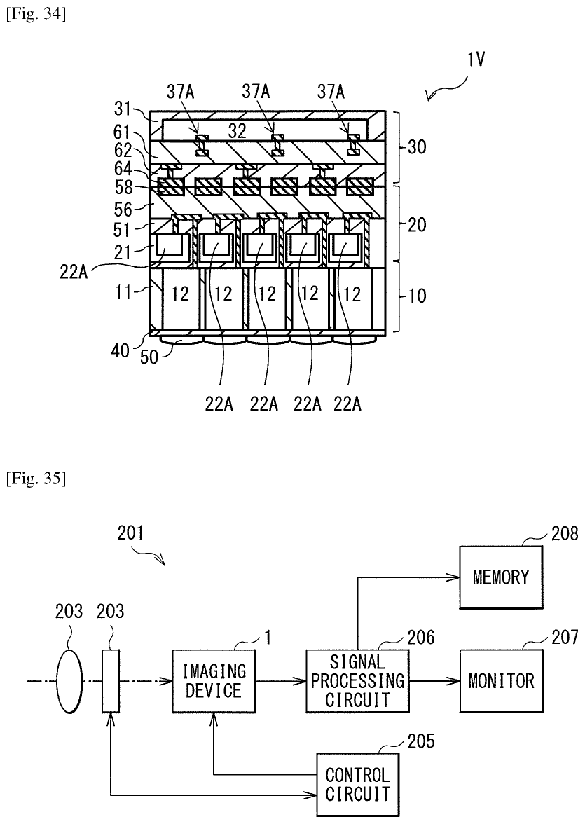

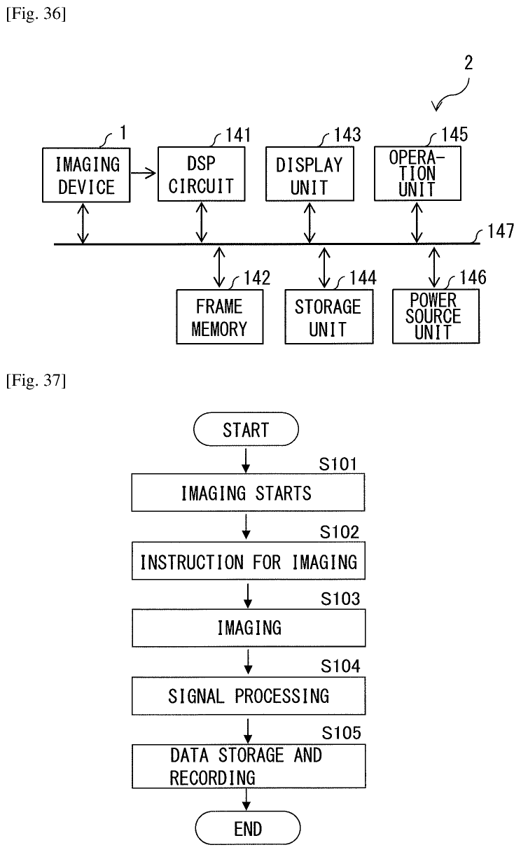

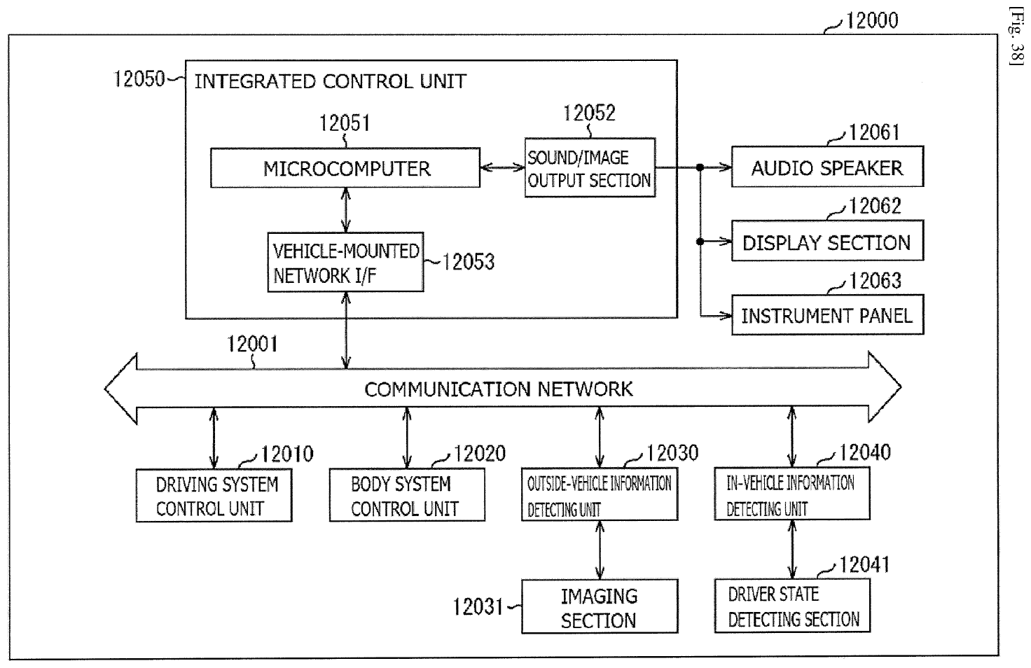

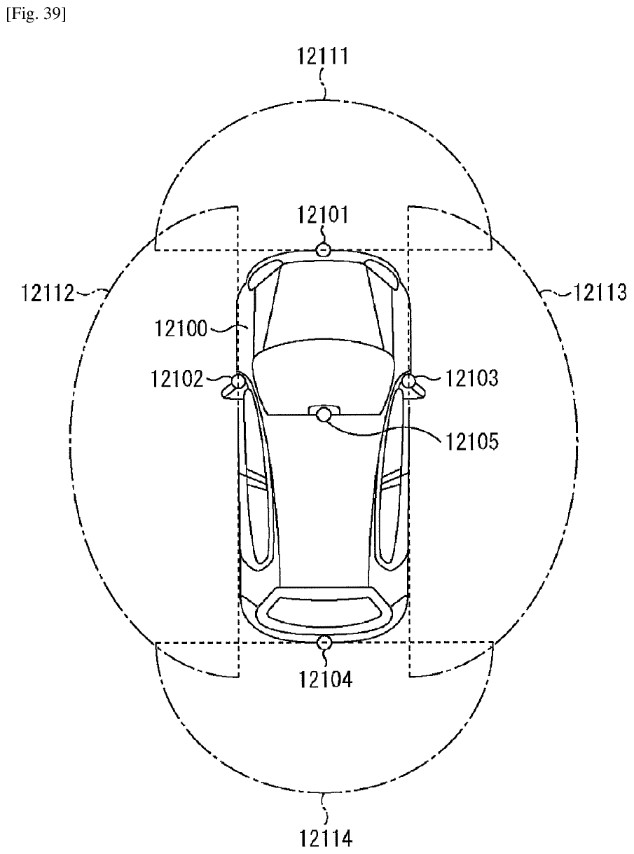

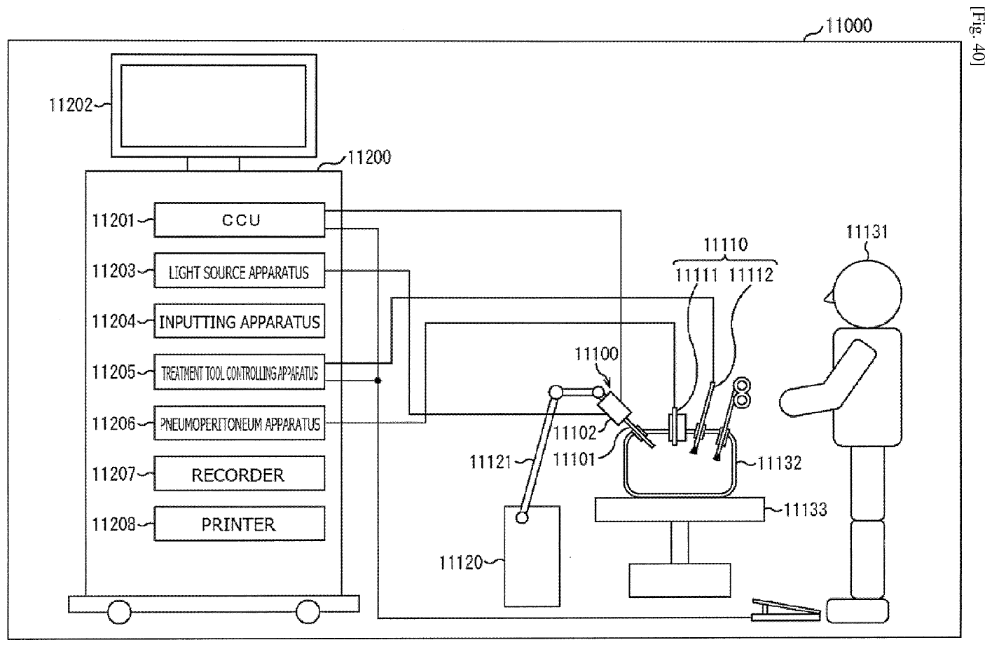

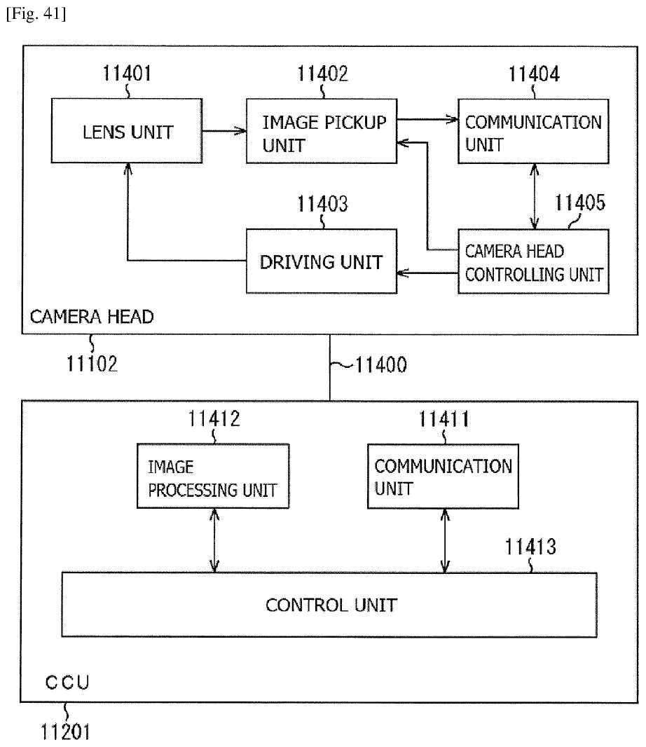

The accompanying drawings are included to provide a further understanding of the technology, and are incorporated in and constitute a part of this specification. The drawings show illustrative embodiments and, together with the specification, serve to explain various principles of the technology.

[FIG. 1] FIG. 1 illustrates an example of a schematic configuration of an imaging device according to an embodiment of the present disclosure.

[FIG. 2] FIG. 2 illustrates an example of a sensor pixel and a readout circuit of the imaging device in FIG. 1.

[FIG. 3A] FIG. 3A illustrates an example of a layout of a first substrate of the imaging device in FIG. 1.

[FIG. 3B] FIG. 3B illustrates an example of a layout of a second substrate of the imaging device in FIG. 1.

[FIG. 3C] FIG. 3C illustrates superposition of FIG. 3A and FIG. 3B.

[FIG. 4] FIG. 4 illustrates an example of a cross-sectional configuration in a vertical direction of the imaging device in FIG. 1.

[FIG. 5A] FIG. 5A illustrates an example of a manufacturing process of the imaging device in FIG. 1.

[FIG. 5B] FIG. 5B illustrates an example of a manufacturing process subsequent to FIG. 5A.

[FIG. 5C] FIG. 5C illustrates an example of a manufacturing process subsequent to FIG. 5B.

[FIG. 5D] FIG. 5D illustrates an example of a manufacturing process subsequent to FIG. 5C.

[FIG. 5E] FIG. 5E illustrates an example of a manufacturing process subsequent to FIG. 5D.

[FIG. 5F] FIG. 5F illustrates an example of a manufacturing process subsequent to FIG. 5E.

[FIG. 5G] FIG. 5G illustrates an example of a manufacturing process subsequent to FIG. 5F.

[FIG. 5H] FIG. 5H illustrates an example of a manufacturing process subsequent to FIG. 5G.

[FIG. 5I] FIG. 5I illustrates an example of a manufacturing process subsequent to FIG. 5H.

[FIG. 6] FIG. 6 illustrates an example of a cross-sectional configuration in the vertical direction of an imaging device according to a modification example A.

[FIG. 7A] FIG. 7A illustrates an example of a manufacturing process of the imaging device in FIG. 6.

[FIG. 7B] FIG. 7B illustrates an example of a manufacturing process subsequent to FIG. 7A.

[FIG. 7C] FIG. 7C illustrates an example of a manufacturing process subsequent to FIG. 7B.

[FIG. 8] FIG. 8 illustrates an example of a sensor pixel and a readout circuit of an imaging device according to a modification example B.

[FIG. 9] FIG. 9 illustrates an example of a sensor pixel and a readout circuit of an imaging device according to a modification example C.

[FIG. 10] FIG. 10 illustrates an example of a sensor pixel and a readout circuit of an imaging device according to a modification example D.

[FIG. 11A] FIG. 11A illustrates an example of a sensor pixel and a readout circuit of an imaging device according to a modification example E.

[FIG. 11B] FIG. 11B illustrates an example of a signal processing circuit of the imaging device according to a modification example E.

[FIG. 12] FIG. 12 illustrates an example of a signal processing circuit of an imaging device according to a modification example F.

[FIG. 13] FIG. 13 illustrates an example of a signal processing circuit of an imaging device according to a modification example G.

[FIG. 14] FIG. 14 illustrates an example of a signal processing circuit of an imaging device according to a modification example H.

[FIG. 15] FIG. 15 illustrates an example of a signal processing circuit of an imaging device according to a modification example I.

[FIG. 16] FIG. 16 illustrates an example of a cross-sectional configuration in a horizontal direction of an imaging device according to a modification example J.

[FIG. 17] FIG. 17 illustrates an example of a cross-sectional configuration in the horizontal direction of the imaging device according to the modification example J.

[FIG. 18] FIG. 18 illustrates an example of a cross-sectional configuration in the horizontal direction of the imaging device according to the modification example J.

[FIG. 19] FIG. 19 illustrates an example of a cross-sectional configuration in the horizontal direction of the imaging device according to the modification example J.

[FIG. 20] FIG. 20 illustrates an example of a cross-sectional configuration in the horizontal direction of the imaging device according to the modification example J.

[FIG. 21] FIG. 21 illustrates an example of a cross-sectional configuration in the horizontal direction of the imaging device according to the modification example J.

[FIG. 22] FIG. 22 illustrates an example of a cross-sectional configuration in the vertical direction of an imaging device according to a modification example K.

[FIG. 23] FIG. 23 illustrates an example of a cross-sectional configuration in the vertical direction of an imaging device according to a modification example L.

[FIG. 24] FIG. 24 illustrates an example of a cross-sectional configuration in the horizontal direction of an imaging device according to a modification example M.

[FIG. 25] FIG. 25 illustrates an example of a cross-sectional configuration in the horizontal direction of the imaging device according to the modification example M.

[FIG. 26] FIG. 26 illustrates an example of a cross-sectional configuration in the horizontal direction of an imaging device according to a modification example N.

[FIG. 27] FIG. 27 illustrates an example of a cross-sectional configuration in the horizontal direction of an imaging device according to a modification example O.

[FIG. 28] FIG. 28 illustrates an example of a cross-sectional configuration in the horizontal direction of an imaging device according to a modification example P.

[FIG. 29] FIG. 29 illustrates an example of a cross-sectional configuration in the horizontal direction of an imaging device according to a modification example Q.

[FIG. 30] FIG. 30 illustrates an example of a cross-sectional configuration in the horizontal direction of an imaging device according to a modification example R.

[FIG. 31] FIG. 31 illustrates an example of a circuit configuration of an imaging device according to a modification example S.

[FIG. 32] FIG. 32 illustrates an example of an imaging device according to a modification example T including three substrates that are stacked.

[FIG. 33] FIG. 33 illustrates an example in which a logic circuit of an imaging device according to a modification example U is separated to be provided in a substrate including a sensor pixel and a substrate including a readout circuit.

[FIG. 34] FIG. 34 illustrates an example in which a logic circuit of an imaging device according to a modification example V is provided in a third substrate.

[FIG. 35] FIG. 35 is a block diagram illustrating an example of a schematic configuration of an electronic apparatus including the imaging device according to any of the foregoing embodiment and the modification examples thereof.

[FIG. 36] FIG. 36 illustrates an example of a schematic configuration of an imaging system including the imaging device according to any of the foregoing embodiment and the modification examples thereof.

[FIG. 37] FIG. 37 illustrates an example of an imaging procedure in the imaging system in FIG. 36.

[FIG. 38] FIG. 38 is a block diagram depicting an example of schematic configuration of a vehicle control system.

[FIG. 39] FIG. 39 is a diagram of assistance in explaining an example of installation positions of an outside-vehicle information detecting section and an imaging section.

[FIG. 40] FIG. 40 is a view depicting an example of a schematic configuration of an endoscopic surgery system.

[FIG. 41] FIG. 41 is a block diagram depicting an example of a functional configuration of a camera head and a camera control unit (CCU).

### DESCRIPTION OF EMBODIMENTS

Some embodiments of the present disclosure are described in detail below with reference to the drawings. It is to be noted that description is given in the following order.

### 1. EMBODIMENT (IMAGING DEVICE) . . . FIGS. 1 to 5I

An example in which a first signal processing circuit is provided in a second substrate

### 2. MODIFICATION EXAMPLES (IMAGING DEVICE)

Modification Example A: an example in which a first transistor includes a silicide layer . . . FIGS. 6 to 7C

Modification Example B: an example in which the first signal processing circuit includes an NMOS and a PMOS . . . FIG. 8

Modification Example C: an example in which the first signal processing circuit is shared among four pixels . . . FIG. 9

Modification Example D: an example in which the first signal processing circuit is shared among four pixels . . . FIG. 10

Modification Example E: an example in which the first signal processing circuit includes a load transistor . . . FIGS. 11A and 11B

Modification Example F: an example in which the signal processing circuit includes a PMOS input type differential input circuit . . . FIG. 12

Modification Example G: an example in which the signal processing circuit includes a SAR type ADC . . . FIG. 13

Modification Example H: an example in which the signal processing circuit includes an ADC including a ΔΣ core . . . FIG. 14

Modification Example I: an example in which a transistor of the first signal processing circuit includes a high-voltage driven transistor . . . FIG. 15

Modification Example J: an example in which the first signal processing circuit is shared among four pixels . . . FIGS. 16 to 21

Modification Example K: an example in which a flat type transfer gate electrode TG is used . . . FIG. 22

Modification Example L: an example in which Cu-Cu bonding is used at an outer edge of a panel . . . FIG. 23

Modification Example M: an example in which an offset is provided between a sensor pixel and a readout circuit . . . FIGS. 24 and 25

Modification Example N: an example in which a silicon substrate including the first signal processing circuit has an island shape . . . FIG. 26

Modification Example O: an example in which a silicon substrate including the first signal processing circuit has an island shape . . . FIG. 27

Modification Example P: an example in which a FD is shared among four sensor pixels . . . FIG. 28

Modification Example Q: an example in which an FD is shared among four sensor pixels . . . FIG. 29
Modification Example R: an example in which an FD is shared among four sensor pixels . . . FIG. 30
Modification Example S: an example in which a column signal processing circuit includes a typical column ADC circuit . . . FIG. 31
Modification Example T: an example in which an imaging device includes three substrates that are stacked . . . FIG. 32
Modification Example U: an example in which a logic circuit is provided in a first substrate and a second substrate . . . FIG. 33
Modification Example V: an example in which a logic circuit is provided in a third substrate . . . FIG. 34
Modification Example W: an example in which an n-type and a p-type of semi-conductor regions are reversed

### 3. APPLICATION EXAMPLES

Application Example 1: an example in which the imaging device according to any of the foregoing embodiment and the modification examples thereof is applied to an electronic apparatus . . . FIG. 35
Application Example 2: an example in which the imaging device according to any of the foregoing embodiment and the modification examples thereof is applied to an imaging system . . . FIGS. 36 and 37

### 4. FURTHER APPLICATION EXAMPLES

Further Application Example 1: an example in which the imaging device according to any of the foregoing embodiment and the modification examples thereof is applied to a mobile body . . . FIGS. 38 and 39
Further Application Example 2: an example in which the imaging device according to any of the foregoing embodiment and the modification examples thereof is applied to a surgery system . . . FIGS. 40 and 41

### 1. EMBODIMENT

### Configuration Example

FIG. 1 illustrates an example of a schematic configuration of an imaging device 1 according to an embodiment of the present disclosure. The imaging device 1 includes three substrates, i.e., a first substrate 10, a second substrate 20, and third substrate 30. The imaging device 1 has a three-dimensional configuration in which three substrates, i.e., the first substrate 10, the second substrate 20, and the third substrate 30 are bonded together. The first substrate 10, the second substrate 20, and the third substrate 30 are stacked in this order.

The first substrate 10 includes a plurality of sensor pixels (or sensor portions) 12 that perform photoelectric conversion, and output a signal charge (or electric charge). The first substrate 10 corresponds to a specific but non-limiting example of a “first substrate” in an embodiment of the present disclosure. The sensor pixels 12 corresponds to a specific but non-limiting example of “sensor pixels” in an embodiment of the present disclosure. The plurality of sensor pixels 12 are provided in rows and columns in a pixel region 13 in the first substrate 10.

The second substrate 20 includes first signal processing circuits 22A on a semi-conductor substrate 21. One of the first signal processing circuits 22A is provided for each of the sensor pixels 12. The second substrate 20 corresponds to a specific but non-limiting example of a “second substrate” in an embodiment of the present disclosure. The first signal processing circuit 22A corresponds to a specific but non-limiting example of a “first signal processing circuit” in an embodiment of the present disclosure. The first signal processing circuit 22A is included in a readout circuit 22 that outputs a pixel signal on the basis of the signal charge outputted from the sensor pixel 12. The second substrate 20 includes a plurality of pixel drive lines 23 extending along a row direction. Moreover, a signal readout line 24A is provided in a stage subsequent to the readout circuit 22. The signal readout line 24A may be provided in any of the second substrate 20 and the third substrate 30.

The third substrate 30 includes second signal processing circuits 22B and a logic circuit 32 on a semiconductor substrate 31. The logic circuit 32 performs processing on the pixel signal. The third substrate 30 corresponds to a specific but non-limiting example of a “third substrate” in an embodiment of the present disclosure. The logic circuit 32 corresponds to a specific but non-limiting example of a logic circuit” in an embodiment of the present disclosure. One of the second signal processing circuits 22B is provided for each of the sensor pixels 12. The first signal processing circuit 22A and the second signal processing circuit 22B are included in the readout circuit 22. One readout circuit 22 is provided for each of the sensor pixels 12. The logic circuit 32 includes, for example, a vertical drive circuit 33, a signal processing circuit 34, a horizontal drive circuit 35, and a system control circuit 36. The readout circuit 22 is coupled to the signal processing circuit 34 through the signal readout line 24A. The signal processing circuit 34 is coupled to the horizontal drive circuit 35. The logic circuit 32 (specifically, the horizontal drive circuit 35) outputs an output voltage Vout per sensor pixel 12 to an external unit. In the imaging device 1, the second signal processing circuit 22B is provided in the third substrate 30. Moreover, in the imaging device 1, the signal processing circuit 34 is provided in the third substrate 30; however, the entirety or a portion of the signal processing circuit 34 may be provided in the second substrate 20. Further, in the imaging device 1, the vertical drive circuit 33 is provided in the third substrate 30; however, the vertical drive circuit 33 may be provided in the first substrate 10 and the second substrate 20.

In the imaging device 1, the readout circuit 22 includes an analog-to-digital conversion circuit, i.e., an A/D converter. In the imaging device 1, the A/D converter is provided for each of the sensor pixels 12. The readout circuit 22 performs correlated double sampling (CDS) processing on the pixel signal outputted from each of the sensor pixels 12. The readout circuit 22 performs, for example, the CDS processing to extract a signal level of the pixel signal and hold pixel data (the pixel signal) corresponding to an amount of light received by each of the sensor pixels 12, i.e., a signal charge amount. For example, the horizontal drive circuit 35 sequentially outputs the pixel data held by the readout circuit 22 to an external unit. For example, the system control circuit 36 controls driving of respective blocks, i.e., the vertical drive circuit 33, the signal processing circuit 34, and the horizontal drive circuit 35 in the logic circuit 32.

In the imaging device 1, a circuit including a combination of the readout circuit 22 and the signal processing circuit 34 may include the A/D converter. Even in this case, the A/D converter is provided for each of the sensor pixels 12. The A/D converter includes a comparison circuit, a latch storage unit, and any other component. The comparison circuit includes a differential input circuit, a voltage conversion circuit, a positive feedback circuit, and any other component. For example, the readout circuit 22 includes a differential input circuit included in the A/D converter, and the signal processing circuit 34 includes a portion excluding the differential input circuit of the A/D converter. Alternatively, the readout circuit 22 may include a comparison circuit included in the A/D converter, and the signal processing circuit 34 may include a portion excluding the comparison circuit of the A/D converter. For example, the signal processing circuit 34 performs signal processing on a signal from the readout circuit 22, and holds obtained pixel data, and the horizontal drive circuit 35 sequentially outputs the pixel data held by the signal processing circuit 34 to an external unit. The signal processing circuit 34 may be provided for each of the sensor pixels 12, or may be provided for each of columns of the sensor pixels 12 in the pixel region 13. A portion of the signal processing circuit 34 may be provided for each of the sensor pixels 12, and the remaining portion may be provided for each of the columns.

Moreover, in the imaging device 1, the readout circuit 22 is provided for each of the sensor pixels 12; however, the readout circuit 22 may be shared among two or more, for example, four of the sensor pixels 12. In this case, the signal processing circuit 34 may be provided for each of groups of the sensor pixels 12 among which the readout circuit 22 is shared, or may be provided for each of columns of the groups of the sensor pixels 12. A portion of the signal processing circuit 34 may be provided for each of the groups of the sensor pixels 12, and the remaining portion of the signal processing circuit 34 may be provided for each of the columns.

FIG. 2 illustrates an example of the sensor pixel 12 and the readout circuit 22. In the present embodiment, one readout circuit 22 is provided for each of the sensor pixels 12. The readout circuit 22 includes the first signal processing circuit 22A and the second signal processing circuit 22B.

Each of the sensor pixels 12 includes, for example, a photodiode PD, a transfer transistor TX, and a floating diffusion FD. The transfer transistor TX is electrically coupled to the photodiode PD. The floating diffusion VD temporarily holds a charge outputted from the photodiode PD through the transfer transistor TX. The photodiode PD performs photoelectric conversion to generate a signal charge corresponding to the amount of received light. A cathode of the photodiode PD is electrically coupled to a source of the transfer transistor TX, and an anode of the photodiode PD is electrically coupled to a reference potential line, for example, a ground. A drain of the transfer transistor TX is electrically coupled to the floating diffusion FD, and a gate of the transfer transistor TX is electrically coupled to the pixel drive line 23. The transfer transistor TX includes, for example, an n-channel metal oxide semiconductor (NMOS) transistor. Each of the sensor pixels 12 is provided in the first substrate 10.

The floating diffusion FD is electrically coupled to an input terminal of the first signal processing circuit 22A included in the readout circuit 22. The first signal processing circuit 22A includes a first analog transistor. The first analog transistor includes, for example, an amplification transistor AMP, a reference signal input transistor (REF), and a current source transistor (Vb). The amplification transistor AMP, the reference signal input transistor (REF), and the current source transistor (Vb) correspond to specific but non-limiting examples of a “first analog transistor” in an embodiment of the present disclosure. Each of the amplification transistor AMP, the reference signal input transistor (REF), and the current source transistor (Vb) includes an NMOS transistor. The first signal processing circuit 22A further includes a reset transistor RST. The reset transistor RST includes an NMOS transistor. The first signal processing circuit 22A is provided in the second substrate 20. Moreover, although not illustrated in FIG. 2, an FD transfer transistor FDG may be provided.

In the imaging device 1 according to the present embodiment, the first signal processing circuit 22A is included in a portion of the readout circuit 22. The first signal processing circuit 22A includes the amplification transistor AMP, the reference signal input transistor REF, and the current source transistor Vb that are included in the differential input circuit. The differential input circuit is included, for example, in a portion of the comparison circuit included in the A/D converter. The first signal processing circuit 22A may include another analog transistor. For example, the first signal processing circuit 22A may include a transistor such as the reset transistor RST coupled to the floating diffusion FD, the select transistor SEL (if the select transistor SEL is provided), or the FD transfer transistor FDG (if the FD transfer transistor FDG is provided). The amplification transistor AMP has a higher noise reduction effect upon increasing an occupied area more than other transistors. Accordingly, the first signal processing circuit 22A preferably includes the amplification transistor AMP.

The readout circuit 22 further includes the second signal processing circuit 22B. The second signal processing circuit 22B includes a second analog transistor. The second analog transistor includes, for example, a transistor PTR1 and a transistor PTR2. Each of the transistor PTR1 and the transistor PTR2 includes a p-channel metal oxide semi-conductor (PMOS) transistor. The second signal processing circuit 22B is provided in the third substrate 30.

The amplification transistor AMP, the reference signal input transistor REF, the current source transistor Vb, the transistor PTR1, and the transistor PTR2 are included in the differential input circuit. An input terminal of the differential input circuit serves as a gate of the amplification transistor AMP, and an output terminal of the differential input circuit serves as a drain of the amplification transistor AMP. The amplification transistor AMP serves both as a transistor that outputs a voltage signal corresponding to the signal charge from the sensor pixel 12 and a portion of the differential input circuit. A source of the reset transistor RST is electrically coupled to the floating diffusion FD, and a drain of the reset transistor RST is electrically coupled to the drain of the amplification transistor AMP.

In a case where the transfer transistor TX is turned to an ON state, the transfer transistor TX transfers a charge of the photodiode PD to the floating diffusion FD. A gate, i.e., a transfer gate electrode TG of the transfer transistor TX extends, for example, from a front surface of a semiconductor substrate 11 to a depth reaching the photodiode PD through a well layer 42, as illustrated in FIG. 4 to be described later. The reset transistor RST resets a potential of the floating diffusion FD to a predetermined potential. In a case where the reset transistor RST is turned to the ON state, the potential of the floating diffusion FD is reset to a potential of a power source line VDD. The select transistor SEL is provided as necessary, and controls an output timing of the pixel signal from the readout circuit 22. The amplification transistor AMP includes a source follower amplifier. The amplification transistor AMP outputs a pixel signal of a voltage corresponding to a level of a charge generated by the photodiode PD and held by the floating diffusion FD. The pixel signal of the voltage is outputted from the differential input circuit including the amplification transistor AMP to a circuit in a stage subsequent to the differential input circuit (upon turning the select transistor SEL to the ON state in a case where the select transistor SEL is provided).

For example, a voltage conversion circuit, a positive feedback circuit, and any other component are provided in a stage subsequent to the differential input circuit. The differential input circuit, the voltage conversion circuit, the positive feedback circuit, and the other component are included in the comparison circuit. For example, a latch control circuit, a latch storage unit, and any other component are provided in a stage subsequent to the comparison circuit. The comparison circuit, the latch storage unit, and the other component are included in the A/D converter. In the imaging device 1, one A/D converter is provided for each of the sensor pixels 12. In the imaging device 1, for example, circuits in a portion in a stage subsequent to the differential input circuit of the A/D converter are included in the second signal processing circuit 22B or the signal processing circuit 34. For example, circuits from the floating diffusion FD to the A/D converter may correspond to the readout circuit 22. Alternatively, circuits to the differential input circuit out of the circuits from the floating diffusion FD to the A/D converter may correspond to the readout circuit 22. Alternatively, a circuit appropriately selected from the circuits from the floating diffusion FD to the A/D converter may correspond to the readout circuit 22. For example, the NMOS transistors of the readout circuit 22 are provided in the second substrate 20 as the first signal processing circuit 22A. Moreover, the PMOS transistors of the readout circuit 22 are provided in the third substrate 30 as the second signal processing circuit 22B.

The FD transfer transistor FDG is used to switch conversion efficiency. In general, the pixel signal is small upon shooting at a dark place. In a case where conversion from a charge to a voltage is performed, on the basis of Q=CV, an increase in a capacity of the floating diffusion FD, i.e., an FD capacity C causes a decrease in V in a case where the charge is converted into the voltage by the amplification transistor AMP. In contrast, the pixel signal is large upon shooting at a bright place; therefore, in a case where the FD capacity C is not sufficiently large, it is difficult for the floating diffusion FD to receive the charge of the photodiode FD. Moreover, in order to prevent V from becoming excessively large in the case where the charge is converted into the voltage by the amplification transistor AMP, in other words, in order for V to become small, it is necessary to increase the FD capacity C. Accordingly, in a case where the FD transfer transistor FDG is turned on, the entire FD capacity C is increased by a gate capacity of the FD transfer transistor FDG. In contrast, in a case where the FD transfer transistor FDG is turned off, the entire FD capacity C is decreased. Thus, the FD capacity C is variable through turning on and off the FD transfer transistor FDG, which makes it possible to switch the conversion efficiency.

FIG. 3A illustrates an example of a layout of the first substrate 10 of the imaging device 1. The transfer transistor TX and power source lines (PWL and VSS) are disposed in one sensor pixel 12. The photodiode PD is provided in a portion excluding the transfer transistor TX and the power source lines (PWL and VSS). FIG. 3B illustrates an example of a layout of the second substrate 20 of the imaging device 1. The amplification transistor AMP, the reference signal input transistor REF, the current source transistor Vb, and the reset transistor RST are disposed in one sensor pixel 12. FIG. 3C is superposition of the layout in FIG. 3A and the layout in FIG. 3B. As can be seen from FIG. 3C, the current source transistor Vb is located close to the transfer transistor TX and the power source lines (PWL and VSS) and partially overlaps the transfer transistor TX and the power source lines (PWL and VSS); therefore, it is difficult to dispose the current source transistor Vb on the same substrate as the transfer transistor TX and the power source lines (PWL and VSS). In the present embodiment, the transfer transistor TX and the power source lines (PWL and VSS) are disposed in the first substrate 10, and the amplification transistor AMP, the reference signal input transistor REF, the current source transistor Vb, and the reset transistor RST are disposed in the second substrate 20, and the first substrate 10 and the second substrate 20 are stacked. Thus, disposition as one pixel is possible.

FIG. 4 illustrates an example of a cross-sectional configuration in a vertical direction of the imaging device 1. FIG. 4 illustrates a cross-sectional configuration at a position opposed to the sensor pixel 12 of the imaging device 1. The imaging device 1 includes the first substrate 10, the second substrate 20, and the third substrate 30 that are stacked in this order, and further includes color filters 40 and light-receiving lenses 50 on a back surface side, i.e., a light incident surface side of the first substrate 10. One of the color filters 40 and one of the light-receiving lenses 50 are provided for each of the sensor pixels 12, for example. In other words, the imaging device 1 is of a back-side illumination type.

The first substrate 10 is configured through stacking an insulation layer 46 on the semiconductor substrate 11. The insulation layer 46 corresponds to a portion of an interlayer insulation film 51. The insulation layer 46 is provided in a gap between the semiconductor substrate 11 and the semiconductor substrate 21 to be described later. The semiconductor substrate 11 includes a silicon substrate. The semiconductor substrate 11 includes a p-well layer 42 in a portion of a front surface thereof and its vicinity, and includes the photodiode PD of a conductivity type different from that of the p-well layer 42 in a region other than the portion of the front surface and its vicinity, that is, a region deeper than the p-well layer 42. The p-well layer 42 includes a p-type semiconductor region. The photodiode PD includes a semiconductor region of a conductivity type (specifically, n-type) different from that of the p-well layer 42. The semiconductor substrate 11 includes, in the p-well layer 42, the floating diffusion FD as a semiconductor region of a conductivity type (specifically n-type) different from that of the p-well layer 42.

The first substrate 10 includes the photodiode PD, the transfer transistor TX including the transfer gate electrode TG, and the floating diffusion FD that are provided for each of the sensor pixels 12. The transfer gate electrode TG includes a vertical gate and a gate electrode of the FD transfer transistor FDG. The vertical gate extracts a charge from the photodiode PD, and the gate electrode of the FD transfer transistor FDG is provided on a front surface of the semiconductor substrate 11. In the first substrate 10, the transfer transistor TX and the floating diffusion FD are provided in a portion on a front surface side (a side opposite to the light incident surface side, i.e., a side on which the second substrate 20 is located) of the semiconductor substrate 11. The first substrate 10 includes an element separator 43 that separates the respective sensor pixels 12. The element separator 43 is provided to extend in a direction of a normal to the semiconductor substrate 11 (a direction perpendicular to the surface of the semiconductor substrate 11). The element separator 43 is provided between two adjacent ones of the sensor pixels 12. The element separator 43 electrically separates the adjacent sensor pixels 12 from each other. The element separator 43 includes, for example, silicon oxide. The element separator 43 penetrates through the semiconductor substrate 11, for example. The first substrate 10 further includes a p-well layer 44 in contact with a side surface on a side on which the photodiode PD is located of the element separator 43. The p-well layer 44 includes a semiconductor region of a conductivity type (specifically, p-type) different from that of the photodiode PD. A p-well layer 44A is provided at an interface between the semiconductor substrate 11 and the insulation layer 46. The p-well layer 44A includes a semiconductor region having the same conductivity type (specifically, p-type) as that of the p-well layer 42 and higher concentration than the p-well layer 42.

The first substrate 10 further includes, for example, a fixed charge film 45 in contact with a back surface of the semiconductor substrate 11. The fixed charge film 45 is negatively charged to suppress generation of a dark current caused by an interface level on a light reception surface side of the semiconductor substrate 11. The fixed charge film 45 includes, for example, an insulation film having a negative fixed charge. Non-limiting examples of a material of such an insulation film include hafnium oxide, zircon oxide, aluminum oxide, titanium oxide, and tantalum oxide. A hole accumulation layer is formed at an interface on the light reception surface side of the semiconductor substrate 11 by an electric field induced by the fixed charge film 45. The hole accumulation layer suppresses generation of electrons from the interface. The color filter 40 is provided on the back surface side of the semiconductor substrate 11. The color filter 40 is provided in contact with the fixed charge film 45, for example, and is provided at a position opposed to the sensor pixel 12 with the fixed charge film 45 interposed therebetween. The light-receiving lens 50 is provided in contact with the color filter 40, for example, and is provided at a position opposed to the sensor pixel 12 with the color filter 40 and the fixed charge film 45 interposed therebetween.

The second substrate 20 is configured through stacking an insulation layer 52 on the semiconductor substrate 21. The insulation layer 52 corresponds to a portion of the interlayer insulation film 51. The insulation layer 52 is provided in a gap between the semiconductor substrate 21 and the semiconductor substrate 31. The semiconductor substrate 21 includes a silicon substrate. The second substrate 20 includes the first signal processing circuits 22A, one of which is provided for each of the sensor pixels 12. The second substrate 20 includes the first signal processing circuits 22A in a portion on a front surface side (a side on which the third substrate 30 is located) of the semiconductor substrate 21. The second substrate 20 is bonded to the first substrate 10 in such a fashion that a back surface of the semiconductor substrate 21 is opposed to the front surface side of the semiconductor substrate 11. In other words, the second substrate 20 is bonded to the first substrate 10 in a face-to-back fashion. The second substrate 20 further includes an insulation layer 53 in the same layer as the semiconductor substrate 21. The insulation layer 53 penetrates through the semiconductor substrate 21. The insulation layer 53 corresponds to the interlayer insulation film 51. The insulation layer 53 is provided to cover a side surface of a through wiring line 54 to be described later.

The first signal processing circuit 22A includes, for example, the amplification transistor AMP, the reference signal input transistor REF, and the current source transistor Vb. Each of the amplification transistor AMP, the reference signal input transistor REF, and the current source transistor Vb includes an analog transistor. The amplification transistor AMP includes a p-type channel formation region (or channel region) of the semiconductor substrate 21, a gate electrode G1, and n-type source-drain regions SD1. The gate electrode G1 is provided on the channel formation region with a gate insulation film interposed therebetween. The source-drain regions SD1 are provided in portions, corresponding to both side portions of the gate electrode G1, of the semiconductor substrate 21 to interpose the channel formation region therebetween. As with the amplification transistor AMP, the reference signal input transistor REF includes a gate electrode G2 on the p-type channel formation region of the semiconductor substrate 21 with the gate insulation film interposed therebetween, and includes n-type source-drain regions SD2 in portions, corresponding to both side portions of the gate electrode G2, of the semiconductor substrate 21. As with the amplification transistor AMP, the current source transistor Vb includes a gate electrode G3 on the p-type channel formation region of the semiconductor substrate 21 with the gate insulation film interposed therebetween, and includes n-type source-drain regions SD3 in portions, corresponding to both side portions of the gate electrode G3, of the semiconductor substrate 21.

A stacking body including the first substrate 10 and the second substrate 20 includes the interlayer insulation film 51 and the through wiring lines 54 provided in the interlayer insulation film 51. The stacking body described above includes the through wiring lines 54, one of which is provided for each of the sensor pixels 12. The through wiring lines 54 each extend along a direction of a normal to the semiconductor substrate 21, and are provided to penetrate through a portion including the insulation layer 53 of the interlayer insulation film 51. The first substrate 10 and the second substrate 20 are electrically coupled to each other through the through wiring lines 54. Specifically, the through wiring lines 54 each are electrically coupled to the floating diffusion FD and a coupling wiring line 55 to be described later.

The stacking body including the first substrate 10 and the second substrate 20 further includes through wiring lines 47 and 48 (refer to FIG. 16 to be described later) provided in the interlayer insulation film 51. The stacking body described above includes the through wiring lines 47, one of which is provided for each of the sensor pixels 12, and includes the through wiring lines 48, one of which is provided for each of the sensor pixels 12. The through wiring lines 47 and 48 each extend along the direction of the normal to the semiconductor substrate 21, and are provided to penetrate through a position including the insulation layer 53 of the interlayer insulation film 51. The first substrate 10 and the second substrate 20 are electrically coupled to each other through the through wiring lines 47 and 48. Specifically, the through wiring lines 47 each are electrically coupled to the p-well layer 42 of the semiconductor substrate 11 and a wiring line in the second substrate 20. The through wiring lines 48 each are electrically coupled to the transfer gate electrode TG and the pixel drive line 23.

The second substrate 20 includes a plurality of coupling sections 59 in the insulation layer 52, for example. The plurality of coupling sections 59 are electrically coupled to the readout circuit 22 and the semiconductor substrate 21. The second substrate 20 further includes, for example, a wiring layer 56 on the insulation layer 52. The wiring layer 56 includes, for example, an insulation layer 57, the plurality of pixel drive lines 23, and a plurality of signal readout lines 24A. The pixel drive lines 23 and the signal readout lines 24A are provided in the insulation layer 57. The wiring layer 56 further includes a coupling wiring line 55. The coupling wiring line 55 electrically couples the respective through wiring lines 54, which are electrically coupled to the floating diffusions FD included in the sensor pixels 12, from one another. Herein, a total number of the through wiring lines 54 and 48 is larger than a total number of the sensor pixels 12 included in the first substrate 10, and is twice as large as the total number of the sensor pixels 12. Moreover, a total number of the through wiring lines 54, 48, and 47 is larger than the total number of the sensor pixels 12 included in the first substrate 10, and is three times as large as the total number of the sensor pixels 12 included in the first substrate 10.

The wiring layer 56 further includes, for example, a plurality of pad electrodes 58 in the insulation layer 57. Each of the pad electrodes 58 includes, for example, metal such as copper (Cu) and aluminum (Al). Each of the pad electrodes 58 is exposed to a front surface of the wiring layer 56. Each of the pad electrodes 58 is used for electrical coupling between the second substrate 20 and the third substrate 30 and bonding between the second substrate 20 and the third substrate 30. One of the pad electrodes 58 is provided for each of the pixel drive lines 23 and each of the signal readout lines 24A, for example. Herein, a total number of the pad electrodes 58, or a total number of bonding points between the pad electrodes 58 and pad electrodes 64 to be described later is smaller than the total number of the sensor pixels 12 included in the first substrate 10.

The third substrate 30 is configured through stacking an interlayer insulation film 61 on the semiconductor substrate 31, for example. It is to be noted that a front surface of the third substrate 30 is bonded to a front surface of the second substrate 20; therefore, in description of a configuration in the third substrate, a top side and a bottom side are opposite to those in the drawings. The semiconductor substrate 31 includes a silicon substrate. The third substrate 30 includes the second signal processing circuit 22B and the logic circuit 32 in a portion on a front surface side of the semiconductor substrate 31. The third substrate 30 further includes, for example, a wiring layer 62 on the interlayer insulation film 61, for example. The wiring layer 62 includes, for example, an insulation layer 63 and a plurality of pad electrodes 64 that are provided in the insulation layer 63. The plurality of pad electrodes 64 are electrically coupled to the second signal processing circuit 22B and the logic circuit 32. Each of the pad electrodes 64 includes, for example copper (Cu). Each of the pad electrodes 64 is exposed to a front surface of the wiring layer 62. Each of the pad electrodes 64 is used for electrical coupling between the second substrate 20 and the third substrate 30 and bonding between the second substrate 20 and the third substrate 30. Moreover, the number of the pad electrodes 64 is not necessarily limited to two or more, and even if the number of the pad electrodes 64 is one, the pad electrode 64 allows for electrical coupling with the second signal processing circuit 22B or the logic circuit 32. The second substrate 20 and the third substrate 30 are electrically coupled to each other by bonding between the pad electrodes 58 and 64. In other words, a gate, i.e., the transfer gate electrode TG of the transfer transistor TX is electrically coupled to the second signal processing circuit 22B or the logic circuit 32 through the through wiring line 54 and the pad electrodes 58 and 64. The third substrate 30 is bonded to the second substrate 20 in such a fashion that a front surface of the semiconductor substrate 31 is opposed to the front surface side of the semiconductor substrate 21. In other words, the third substrate 30 is bonded to the second substrate 20 in a face-to-face fashion.

The second signal processing circuit 22B includes, for example, the transistor PTR1 and the transistor PTR2. Each of the transistor PTR1 and the transistor PTR2 includes an analog transistor. Each of the transistor PTR1 and the transistor PTR2 includes a PMOS transistor. FIG. 4 illustrates one transistor as a representative of the transistor PTR1 and the transistor PTR2. The transistor included in the second signal processing circuit 22B includes a gate electrode G4 on an n-type channel formation region of the semiconductor substrate 31 with a gate insulation film interposed therebetween, and includes p-type source-drain regions SD4 in portions, corresponding to both side portions of the gate electrode G4, of the semiconductor substrate 31.

The logic circuit 32 includes, for example, a complementary metal oxide semi-conductor (CMOS) transistor. FIG. 4 illustrates one transistor as a representative of the transistor of the logic circuit 32. The transistor included in the logic circuit 32 includes a gate electrode G5 on a channel formation region of the semiconductor substrate 31 with an gate insulation film interposed therebetween, and includes source-drain regions SD5 in portions, corresponding to both side portions of the gate electrode G5, of the semiconductor substrate 31.

Manufacturing Method

Next, description is given of a method of manufacturing the imaging device 1. FIGS. 5A to 5I each illustrate an example of a manufacturing process of the imaging device 1. FIGS. 5A and 5I do not illustrate a portion from a midpoint of the photodiode PD to the light-receiving lens 50.

First, the p-well layer 42, the element separator 43, the p-well layer 44 are formed on the semiconductor substrate 11. Next, the photodiode PD and the transfer gate electrode TG of the transfer transistor TX are formed on the semiconductor substrate 11 (FIG. 5A). Thus, the sensor pixel 12 is formed on the semiconductor substrate 11. On this occasion, it is preferable not to use, as an electrode material used for the sensor pixel 12, a material having low heat resistance such as CoSi₂ and NiSi by a self aligned silicide (salicide) process. As the electrode material used for the sensor pixel 12, a material having high heat resistance is preferably used. Non-limiting examples of the material having high heat resistance include polysilicon. The transfer gate electrode TG of the transfer transistor TX is formed, for example, through forming polysilicon containing phosphorus into a film with a thickness in a range from 50 nm to 300 nm by a chemical vapor deposition (CVD) method and performing pattern processing on the polysilicon by pattern formation of a resist film by a photolithography process and a dry etching process. Alternatively, the transfer gate electrode TG of the transfer transistor TX is formed, for example, through forming polysilicon not containing an impurity into a film with a thickness in a range from 50 nm to 300 nm, adding phosphorus with a dose amount in a range from 1×10¹⁵ ions/cm² to 1×10¹⁶ ions/cm² by ion implantation, and performing pattern processing by a photolithography process and a dry etching process.

Subsequently, the floating diffusion DF and the p-well layer 44A are formed on the front surface of the semiconductor substrate 11 by ion implantation, and thereafter, the insulation layer (pre-metal-dielectric (PMD)) 46 is formed on the semiconductor substrate 11, and is planarized (FIG. 5B). Thus, the first substrate 10 is formed. The planarized insulation layer 46 preferably has a thickness in a range from about 200 nm to about 2 μm.

Next, the semiconductor substrate 21 is bonded onto the first substrate 10 (the insulation layer 46) (FIG. 5C). On this occasion, the semiconductor substrate 21 is thinned as necessary. On this occasion, a thickness of the semiconductor substrate 21 is thinned to a thickness necessary for formation of the first signal processing circuit 22A. The thickness of the semiconductor substrate 21 is generally about several hundreds of nm. However, the semiconductor substrate 21 may be completely depleted depending on a concept of the first signal processing circuit 22A. In such a case, the thickness of the semiconductor substrate 21 may be in a range from several nm to several μm.

Subsequently, the insulation layer 53 is formed in the same layer as the semi-conductor substrate 21 (FIG. 5D). The insulation layer 53 is formed, for example, at a position opposed to the floating diffusion FD. For example, a slit penetrating through the semiconductor substrate 21 is formed in the semiconductor substrate 21 to separate the semiconductor substrate 21 into a plurality of blocks 21A. Next, the insulation layer 53 is formed to be embedded in the slit.

Subsequently, ion implantation is performed on each of the blocks 21A of the semi-conductor substrate 21 to form the channel formation region. Next, a gate insulation film including silicon oxide is formed on a front surface of each of the blocks 21A of the semiconductor substrate 21 by a thermal oxidation method, a CVD method, or any other method. Subsequently, the gate electrodes G1, G2, and G3 are formed. The gate electrodes G1, G2, and G3 are formed, for example, through forming polysilicon containing phosphorus into a film with a thickness in a range from 50 nm to 300 nm by a CVD method, and performing pattern processing on the polysilicon by pattern formation of a resist film by a photolithography process and a dry etching process. Alternatively, the gate electrodes G1, G2, and G3 are formed, for example, through forming polysilicon not containing an impurity into a film with a thickness in a range from 50 nm to 300 nm, adding phosphorus with a dose amount in a range from 1×10¹⁵ ions/cm² to 1×10¹⁶ ions/cm² by ion implantation, and performing pattern processing by a photolithography process and a dry etching process. Next, the source-drain regions SD1, SD2, and SD3 are formed by ion implantation. Thus, the first signal processing circuit 22A including the amplification transistor AMP, the reference signal input transistor REF, the current source transistor Vb, and other components is formed (FIG. 5E). Formation of the gate insulation film by a thermal oxidation method is preferably applicable in a case where a metal material having high heat resistance is used as an electrode material of the sensor pixel 12.

Subsequently, the insulation layer 52 is formed on the semiconductor substrate 21. Thus, the interlayer insulation film 51 including the insulation layers 46, 52, and 53 is formed. Next, heat treatment for impurity activation is performed. On this occasion, an impurity is diffused in the floating diffusion FD and the source-drain regions SD1, SD2, and SD3. Subsequently, a front surface of the insulation layer 52 is planarized, and through holes 51A and 51B are formed in the interlayer insulation film 51 (FIG. 5F). Specifically, the through hole 51B penetrating through the insulation layer 52 is formed at a position, opposed to the gate electrode and the source-drain regions of each of the transistors of the first signal processing circuit 22A, of the insulation layer 52. Moreover, the through hole 51A penetrating through the interlayer insulation film 51 is formed at a position, opposed to the floating diffusion FD (that is, at a position opposed to the insulation layer 53), of the interlayer insulation film 51.

Next, an electrically conductive material is embedded in the through holes 51A and 51B to form the through wiring line 54 in the through hole 51A and form the coupling section 59 in the through hole 51B (FIG. 5F). Embedding of the electrically conductive material in the through holes 51A and 51B is performed, for example, through forming a titanium/titanium nitride film on an inner wall surface of each of the through holes 51A and 51B by a metal-organic CVD (MO-CVD) method, further forming tungsten into a film by a CVD method to embed the tungsten in the through holes 51A and 51B, and removing the electrically conductive material disposed outside the through holes 51A and 51B. Further, the coupling wiring line 55 that electrically couples the through wiring line 54 and the coupling section 59 to each other is formed on the insulation layer 52 (FIG. 5F). Substantially, the insulation layer 57 and the wiring layer 56 including electrically conductive layers such as the pixel drive line 23, the signal readout line 24A, and the pad electrodes 58 are formed on the insulation layer 52. The electrically conductive layers are formed by a damascene method using copper, for example. In the damascene method, for example, an insulation film included in the insulation layer 57 is formed; trenches having patterns of the electrically conductive layers are formed in the insulation film; copper is embedded in the trenches; and copper disposed outside the trenches is removed. Thus, the second substrate 20 is formed (FIG. 5G).

In contrast, the third substrate 30 in which the second signal processing circuit 22B, the logic circuit 32, and the wiring layer 62 are formed is separately formed (FIG. 5H). Subsequently, the second substrate 20 is bonded to the third substrate 30 in such a fashion that the front surface of the semiconductor substrate 21 is opposed to the front surface side of the semiconductor substrate 31 (FIG. 5I). The pad electrodes 58 of the second substrate 20 include copper, and the pad electrodes 64 of the third substrate 30 also include copper. The pad electrodes 58 of the second substrate 20 and the pad electrodes 64 of the third substrate 30 are bonded together by a copper-copper bonding method to electrically couple the second substrate 20 and the third substrate 30 to each other. Next, the color filters 40 and the light-receiving lenses 50 are formed on the back surface side of the first substrate 10. Thus, the imaging device 1 is manufactured.

Operation

In the imaging device 1, light, for example, light with a wavelength in a visible region enters the photodiode PD from the back surface side of the first substrate 10, and thereafter pairs of holes and electrons are generated (photoelectric conversion is performed) in the photodiode PD. The transfer transistor TX is turned to the ON state, which causes a signal charge accumulated in the photodiode PD to be transferred to the floating diffusion FD. The signal charge accumulated in the floating diffusion FD is converted into a voltage signal by the amplification transistor AMP, and the voltage signal is subjected to A/D conversion by the A/D converter included in the readout circuit 22, and is outputted from the horizontal drive circuit 35.

Workings and Effects of Imaging Device 1

In the imaging device 1 according to the present embodiment, the sensor pixels 12 are disposed in the first substrate 10, and the first signal processing circuit 22A that includes the first analog transistor and is included in the readout circuit 22 is disposed in the second substrate 20. The first analog transistor includes the amplification transistor AMP. The sensor pixels 12, and the analog transistor such as the amplification transistor included in the readout circuit are disposed in different substrates, which makes it possible to increase an occupied area of the analog transistor. Such workings and effects are described below with use of a comparative example.

PTL 1 discloses an imaging device including A/D converters, one of which is provided for each of pixels. Herein, the imaging device is achieved by a configuration in which one semiconductor substrate includes a readout circuit including a photodiode, an amplification transistor, and any other component, and a portion of a comparison circuit included in the A/D converter. In such an imaging device, it is desired to reduce noise of the readout circuit including the amplification transistor and other components, and the comparison circuit included in the A/D converter. it is possible to reduce such noise through increasing the occupied area of the analog transistor included in the comparison circuit and any other component, specifically the amplification transistor; however, increasing the occupied area of the amplification transistor makes it difficult to secure an occupied area of the photodiode provided in the same substrate, and makes it difficult to miniaturize pixels and increase the number of pixels.

In the imaging device 1 according to the present embodiment, the sensor pixels 12 are disposed in the first substrate 10, and the analog transistor such as the amplification transistor included in the readout circuit is disposed in the second substrate 20. This makes it possible to increase the occupied area of the analog transistor such as the amplification transistor without decreasing the occupied area of the photodiode. Increasing the occupied area of the analog transistor, specifically the amplification transistor makes it possible to reduce noise.

Moreover, in the imaging device 1 according to the present embodiment, the amplification transistor AMP coupled to the floating diffusion FD also serves as a portion of the differential input circuit of the comparison circuit included in the A/D converter. This makes it possible to reduce the number of transistors and increase the occupied area of the amplification transistor, thereby reducing noise.

Further, in the imaging device 1 according to the present embodiment, one A/D converter as the signal processing circuit is provided for each of sensor pixels. This makes it possible to read a digital pixel signal generated by A/D conversion from each of pixels, which makes it possible to achieve a higher frame rate and imaging characteristics without temporal distortion in a frame.

As described above, in the imaging device 1 according to the present embodiment, the sensor pixels 12 are disposed in the first substrate 10, and the analog transistor is disposed in the second substrate 20, which makes it possible to increase the occupied area of the analog transistor and reduce noise without decreasing the occupied area of the photodiode. cl 2. MODIFICATION EXAMPLES

In the following, description is given of modification examples of the imaging device 1 according to the foregoing embodiment. It is to be noted that in the following modification examples, common components to those in the foregoing embodiment are denoted by same reference numerals.

### Modification Example A

In the foregoing embodiment, a silicide layer is not provided in the analog transistor included in the first signal processing circuit 22A; however, a silicide layer may be provided. The silicide layer is a metal silicide (hereinafter also referred to as “silicide”), such as cobalt silicide (CoSi₂) and nickel silicide (NiSi), prepared with use of a self aligned silicide (salicide) process.

FIG. 6 illustrates an example of a cross-sectional configuration in the vertical direction of an imaging device 1A as a modification example A. The imaging device 1A is a modification example of the imaging device 1 according to the foregoing embodiment. In the imaging device 1A, silicide layers G1A, G2A, and G3A including CoSi₂, NiSi, or any other material are respectively provided on a front surface of the gate electrode G1 of the amplification transistor AMP, a front surface of the gate electrode G2 of the reference signal input transistor REF, and a front surface of the gate electrode G3 of the current source transistor Vb. The amplification transistor AMP, the reference signal input transistor REF, and the current source transistor Vb are included in the first signal processing circuit 22A. In the imaging device 1A, silicified source-drain regions SD1A, SD2A, and SD3A are provided in place of the source-drain regions SD1, SD2, and SD3. The silicide layers G1A, G2A, and G3A, and the silicified source-drain regions SD1A, SD2A, and SD3A are formed by the salicide process. Sidewalls SW1, SW2, and SW3 are provided on both sides of the gate electrodes G1, G2, and G3. The sidewalls SW1, SW2, and SW3 serve as silicide blocks that protect a portion not to be silicified in the salicide process. The imaging device 1A has a similar configuration to that in the foregoing embodiment, except for the configuration described above.

In the imaging device 1A, the silicide layers G1A, G2A, and G3A are respectively provided on the front surfaces of the gate electrodes G1, G2, and G3, and the silicified source-drain regions SD1A, SD2A, and SD3A are provided in place of the source-drain regions SD1, SD2, and SD3. The silicide has low resistance, which makes it possible to remarkably reduce parasitic resistance of the transistor, thereby reducing noise by an improvement in mutual inductance gm.

In general, silicifying a transistor of a substrate including sensor pixels causes an increase in leakage current such as a dark current in a pixel section, a deterioration in image quality such as an increase in bright point, or a decrease in yields. In the imaging device 1A, the transistor provided in a substrate (the second substrate 20) different from the first substrate 10 including the sensor pixels 12 is silicified, which makes it possible to decrease resistance of the transistor without causing an issue such as a decrease in yields resulting from dark current characteristics and an increase in bright points. This makes it possible to decrease parasitic resistance of the transistor, thereby improving processing speed and reducing noise.

Description is given of a method of manufacturing the imaging device 1A illustrated in FIG. 6. FIGS. 7A to 7C each illustrate a manufacturing process of the imaging device 1A. FIGS. 7A to 7C do not illustrate a portion from a midpoint of the photodiode PD to the light-receiving lens 50.

First, processes until the process of stacking the semiconductor substrate 21 on the first substrate 10 and forming the first signal processing circuit 22A including the amplification transistor AMP, the reference signal input transistor REF, the current source transistor Vb, and other components are performed similarly to the processes until the process in FIG. 5E in the foregoing embodiment.

Next, silicon oxide is formed by, for example, a CVD method to entirely cover the amplification transistor AMP, the reference signal input transistor REF, and the current source transistor Vb, and the silicon oxide is etched back to form the sidewalls SW1, SW2, and SW3 on both sides of the gate electrodes G1, G2, and G3. Subsequently, a metal film including cobalt, nickel, or any other metal is entirely formed by, for example, a sputtering method in a state in which front surfaces of the gate electrodes G1, G2, and G3 and the source-drain regions SD1, SD2, and SD3 are exposed. The metal film is formed in contact with silicon on the front surfaces of the gate electrodes G1, G2, and G3 and the source-drain regions SD1, SD2, and SD3. Next, a cap film is formed in an upper layer of the metal film, and heat treatment is performed. Portions where the metal and silicon are in contact with each other are alloyed (metal-silicified) to form the silicide layers G1A, G2A, and G3A and the silicified source-drain regions SD1A, SD2A, and SD3A. In a silicification process, the gate electrodes G1, G2, and G3 and the source-drain regions SD1, SD2, and SD3 may be only partially silicified, or the gate electrodes G1, G2, and G3 and the source-drain regions SD1, SD2, and SD3 may be entirely silicified. Subsequently, the cap layer and an unreacted metal film are removed by a cleaning process, and the silicide remains (FIG. 7A).

It is possible to perform the following processes similarly to the processes in the foregoing embodiment. In other words, the insulation layer 52 is formed on the semi-conductor substrate 21; the through holes 51A and 51B are formed; and the through wiring line 54 and the coupling section 59 are formed. Next, the coupling wiring line 55 is formed (FIG. 7B).

Next, the wriing layer 56 is formed by formation of an insulation film and formation of an electrically conductive layer by a damascene method (FIG. 7C). Subsequently, the second substrate 20 is bonded to the third substrate 30, and the color filters 40 and the light-receiving lenses 50 are formed on the back surface side of the first substrate 10. Thus, the imaging device 1A is manufactured.

In the imaging device 1A, in addition to the effects of the foregoing embodiment, silicifying the transistor provided in the second substrate 20 makes it possible to decrease resistance of the transistor and reduce noise.

### Modification Example B

In the foregoing embodiment, the analog transistor included in the first signal processing circuit 22A includes only NMOS transistors such as the amplification transistor AMP, the reference signal input transistor REF, and the current source transistor Vb; however, the analog transistor are not limited thereto, and may include a PMOS transistor.

FIG. 8 illustrates an example of a sensor pixel and a readout circuit of an imaging device 1B as a modification example B. The imaging device 1B is a modification example of the imaging device 1 according to the foregoing embodiment. In the imaging device 1B, the first signal processing circuit 22A includes the amplification transistor AMP, the reference signal input transistor REF, the current source transistor Vb, the transistor PTR1, and the transistor PTR2. Each of the transistor PTR1 and the transistor PTR2 include a PMOS transistor. In the imaging device 1B, the second signal processing circuit 22B is not provided, and the readout circuit 22 includes only the first signal processing circuit 22A. The readout circuit 22 corresponds to a differential input circuit included in the A/D converter. The readout circuit 22 outputs the pixel signal to the signal readout line 24A, or the signal processing circuit 34 or any other component in a stage subsequent to the signal readout line 24A.

In the imaging device 1B, as the first signal processing circuit 22A, not only MNOS transistors such as the amplification transistor AMP, the reference signal input transistor REF, and the current source transistor Vb but also PMOS transistors such as the transistor PTR1 and the transistor PTR2 are disposed in the second substrate 20. The logic circuit 32, the signal processing circuit 34 such as the A/D converter (excluding a portion corresponding to the differential input circuit), and any other component are disposed in the third substrate 30.

In the imaging device 1B, as with the foregoing embodiment, the analog transistor is disposed in the second substrate 20, which makes it possible to increase the occupied area of the analog transistor and reduce noise without decreasing the occupied area of the photodiode.

### Modification Example C

In the foregoing embodiment, one of the first signal processing circuits 22A is provided for each of the sensor pixels 12; however, one first signal processing circuit 22A may be shared among two or more, for example, four of the sensor pixels 12. Herein, “share” indicates inputting outputs of four sensor pixels 12 to a common one of the first signal processing circuits 22A.

FIG. 9 illustrates an example of a sensor pixel and a readout circuit of an imaging device 1C as a modification example C. The imaging device 1C is a modification example of the imaging device 1 according to the foregoing embodiment. In FIG. 9, the floating diffusions FD of four sensor pixels 12-1, 12-2, 12-3, and 12-4 are coupled to one amplification transistor AMP. Inputting to the amplification transistor AMP is switched by the transfer transistors TX included in the respective sensor pixels 12-1, 12-2, 12-3, and 12-4. A mechanism that controls a transfer timing of each of the sensor pixels 12 and performs A/D conversion is adopted. In the imaging device 1C, one A/D converter is shared among four sensor pixels 12.

In the imaging device 1C, the sensor pixels 12 are disposed in the first substrate 10; the MNOS transistors such as the amplification transistor AMP, the reference signal input transistor REF, and the current source transistor Vb included in the first signal processing circuit 22A are disposed in the second substrate 20; and the PMOS transistors such as the transistor PTR1 and the transistor PTR2 included in the second signal processing circuit 22B are disposed in the third substrate 30. The logic circuit 32 and the signal processing circuit 34 such as the A/D converter (excluding a portion corresponding the differential input circuit) are further disposed in the third substrate 30.

In the imaging device 1C, as with the foregoing embodiment, the analog transistor is disposed in the second substrate 20, which makes it possible to increase the occupied area of the analog transistor and reduce noise without decreasing the occupied area of the photodiode. The number of sensor pixels 12 among which the A/D converter (the first signal processing circuit 22A) is shared is not specifically limited, and is selectable in accordance with a trade-off with speed of A/D conversion.

### Modification Example D

The first signal processing circuit 22A may be shared among two or more, for example, four of the sensor pixels 12 in a circuit configuration different from that of the imaging device 1C.

FIG. 10 illustrates an example of a sensor pixel and a readout circuit of an imaging device 1D as a modification example D. The imaging device 1D is a modification example of the imaging device 1 according to the foregoing embodiment. In FIG. 10, the floating diffusions FD of four sensor pixels 12-1, 12-2, 12-3, and 12-4 are respectively coupled to four amplification transistors AMP1, AMP2, AMP3, and AMP4. The four amplification transistors AMP1, AMP2, AMP3, and AMP4 are respectively coupled to the select transistors SEL1, SE12, SEL3, and SEL4. The signal charge is read from the floating diffusion FD of the sensor pixel 12 selected by the select transistors SEL1, SEL2, SEL3, and SEL4, and the signal charge is converted into a voltage signal. Thereafter, the voltage signal is outputted to the signal readout line 24A, or the signal processing circuit 34 or any other component in a stage subsequent to the signal readout line 24A.

In the imaging device 1D, the sensor pixels 12 are disposed in the first substrate 10. The NMOS transistors such as the amplification transistor AMP, the reference signal input transistor REF, the current source transistor Vb, and the select transistors SEL1, SEL2, SEL3, and SEL4 included in the first signal processing circuit 22A are disposed in the second substrate 20. The PMOS transistors such as the transistor PTR1 and the transistor PTR2 included in the second signal processing circuit 22B are disposed in the third substrate 30. The logic circuit 32, the signal processing circuit 34 such as the A/D converter (excluding a portion corresponding to the differential input circuit), and any other component are disposed in the third substrate 30.

In the imaging device 1D, as with the foregoing embodiment, the analog transistor is disposed in the second substrate 20, which makes it possible to increase the occupied area of the analog transistor and reduce noise without decreasing the occupied area of the photodiode. The number of sensor pixels 12 among which the A/D converter (the first signal processing circuit 22A) is shared is not specifically limited, and is selectable in accordance with a trade-off with speed of A/D conversion.

### Modification Example E

In the imaging device 1, one A/D converter is provided for each of the sensor pixel 12; however, one A/D converter is provided for each of columns of the sensor pixels 12 in the pixel region 13. An imaging device including A/D converters, one of which is provided for each of the sensor pixels 12 is referred to as “imaging device of a pixel ADC type”. Moreover, an imaging device including A/D converters, one of which is provided for each of the columns of the sensor pixels 12 is referred to as “imaging device of a column ADC type”. In the imaging device of the column ADC type, the first signal processing circuit 22A may include the amplification transistor AMP coupled to the floating diffusion FD and a load transistor of the vertical signal line 24.

FIG. 11A illustrates an example of the sensor pixel 12 and the first signal processing circuit 22A included in the readout circuit 22 of the imaging device 1E as a modification example E. As illustrated in FIG. 11A, the sensor pixel 12 includes the photodiode PD, the transfer transistor TX, and the floating diffusion FD. The sensor pixel 12 is disposed in the first substrate 10. The amplification transistor AMP, the reset transistor RST, and the select transistor SEL are coupled to the floating diffusion FD, and the signal charge of the floating diffusion FD is converted into a voltage signal, and the voltage signal is outputted to the vertical signal line 24. The load transistor is provided for the vertical signal line 24. The amplification transistor AMP, the reset transistor RST, the select transistor SEL, and the load transistor described above are included in the first signal processing circuit 22A, and are disposed in the second substrate 20.

FIG. 11B illustrates an example of the signal processing circuit 34 coupled to a stage subsequent to the vertical signal line 24. The signal processing circuit 34 includes an A/D converter. The A/D converter includes a differential input circuit. FIG. 11B corresponds to the differential input circuit. A circuit 34E including an NMOS transistor encircled by a broken line in FIG. 11B is disposed in the second substrate 20, as with the first signal processing circuit 22A. The logic circuit 32, the analog transistor included in the signal processing circuit 34 such as the A/D converter (excluding the circuit 34E), a storage unit, and any other component are disposed in the third substrate 30.

In the imaging device 1E, as with the foregoing embodiment, the analog transistor is disposed in the second substrate 20, which makes it possible to increase the occupied area of the analog transistor and reduce noise without decreasing the occupied area of the photodiode.

A noise reduction effect achieved through increasing a gate width was determined by simulation with use of an imaging device having a circuit configuration illustrated in FIGS. 11A and 11B and having a non-increased gate width, i.e., a one-time gate width of the amplification transistor AMP, and an imaging device having the circuit configuration illustrated in FIGS. 11A and 11B and having an increased gate width, i.e., a 1.5-times gate width of the amplification transistor AMP. While random noise (RN) after CDS processing was 51. 6 μVrsm in the imaging device having the non-increased gate width of the amplification transistor AMP, RN was 48.1 μVrms in a case where the gate width of the amplification transistor AMP was increased by 1.5 times. The RN after the CDS processing was able to be reduced by 6.8%. As conditions of the simulation, a cutoff frequency of a circuit subsequent to the amplification transistor AMP was 2.0 MHz, and a CDS period was 1.9 μS.

### Modification Example F

An imaging device 1F as a modification example F is of the column ADC type. In the imaging device 1E, the differential input circuit includes the NMOS transistor serving as an input unit; however, a PMOS transistor may serve as the input unit.

In the imaging device 1F, as with the imaging device 1E, the sensor pixels 12 are disposed in the first substrate 10. The imaging device 1F includes the first signal processing circuit 22A similar to that in FIG. 11A. The amplification transistor AMP, the reset transistor RST, the select transistor SEL, and the load transistor included in the first signal processing circuit 22A are disposed in the second substrate 20.

FIG. 12 illustrates an example of the signal processing circuit 34 coupled to the stage subsequent to the vertical signal line 24. The signal processing circuit 34 includes an A/D converter. The A/D converter includes a differential input circuit. The differential input circuit of the imaging device 1F is of a PMOS transistor input type. A circuit 34F including the NMOS transistor and the PMOS transistor encircled by a broken line in FIG. 12 is disposed in the second substrate 20, as with the first signal processing circuit 22A. The logic circuit 32, the analog transistor included in the signal processing circuit 34 such as the A/D converter (excluding the circuit 34E), a storage unit, and any other component are disposed in the third substrate 30.

In the imaging device 1F, as with the foregoing embodiment, the analog transistor is disposed in the second substrate 20, which makes it possible to increase the occupied area of the analog transistor and reduce noise without decreasing the occupied area of the photodiode. Moreover, disposing the analog transistor in the second substrate 20 allows for a configuration in which the analog transistor is not provided in the third substrate 30. In general, the analog transistor needs finer characteristic adjustment than a logic transistor. Non-limiting examples of the characteristic adjustment include setting a threshold voltage to a lower voltage than that of a transistor of a logit circuit. The configuration in which the analog transistor is not provided in the third substrate 30 makes it possible to manufacture the third substrate 30 at low cost in a short process.

### Modification Example G

An imaging device 1G as a modification example G is of the column ADC type. The A/D converter provided for each of the columns may be of a successive approximation register (SAR) type.

In the imaging device 1G, as with the imaging device 1E, the sensor pixels 12 are disposed in the first substrate 10. The imaging device 1G includes the first signal processing circuit 22A similar to that in FIG. 11A. The amplification transistor AMP, the reset transistor RST, the select transistor SEL, and the load transistor included in the first signal processing circuit 22A are disposed in the second substrate 20.

FIG. 13 illustrates an example of the signal processing circuit 34 coupled to the stage subsequent to the vertical signal line 24. The signal processing circuit 34 includes an SAR type A/D converter. The A/D converter includes a differential input circuit. The differential input circuit of the imaging device 1G is of a PMOS input type. A voltage digital-to-analog converter (VDAC) is coupled to a reference signal input transistor. A circuit 34G including the NMOS transistor and the PMOS transistor encircled by a broken line in FIG. 13 is disposed in the second substrate 20 as with the first signal processing circuit 22A. In the imaging device 1G, the circuit 34G corresponds to a PMOS input type differential input circuit. A current sense input unit and an low dropout (LDO) circuit of a sample-and-hold circuit are further disposed in the second substrate 20. Thus, the analog transistor included in a portion of the differential input circuit that is included in the A/D converter is disposed in the second substrate 20 in addition to the amplification transistor. The logic circuit 32, a digital-to-analog converter (DAC), the analog transistor (excluding the current sense input unit, the LDO circuit and any other component of the sample-and-hold circuit) such as the A/D converter (excluding the circuit 34G) included in the signal processing circuit 34, a storage unit, and any other component are disposed in the third substrate 30.

In the imaging device 1G, as with the foregoing embodiment, the analog transistor is disposed in the second substrate 20, which makes it possible to increase the occupied area of the analog transistor and reduce noise without decreasing the occupied area of the photodiode. Moreover, disposing the analog transistor in the second substrate 20 allows for a configuration in which the analog transistor is not provided in the third substrate 30. This makes it possible to manufacture the third substrate 30 at low cost in a short process.

### Modification Example H

An imaging device 1H as a modification example H is of the column ADC type. The A/D converter provided for each of the columns may include an A/D converter including a ΔΣ core. In the A/D converter including the ΔΣ core, for example, a current is modulated into a column current source for column readout from a pixel at a feedback destination of an integrator and a quantizer. A ΔΣ modulator is incorporated in the column, which makes it possible to achieve higher speed of processing.

In the imaging device 1H, as with the imaging device 1E, the sensor pixels 12 are disposed in the first substrate 10. The imaging device 1H includes the first signal processing circuit 22A similar to that in FIG. 11A. The amplification transistor AMP, the reset transistor RST, the select transistor SEL, and the load transistor included in the first signal processing circuit 22A are disposed in the second substrate 20.

FIG. 14 illustrates an example of the signal processing circuit 34 coupled to the stage subsequent to the vertical signal line 24. The signal processing circuit 34 includes the A/D converter including the ΔΣ core. The A/D converter includes the ΔΣ core, and includes, in a stage preceding to the ΔΣ core, an input current controller 34H including a sample-and-hold circuit S&H, an LDO circuit, and a voltage-to-current (V2I) circuit. The input current controller 34H is disposed in the second substrate 20 as with the first signal processing circuit 22A. Thus, in addition to the amplification transistor, the analog transistor included in a portion of the A/D converter is disposed in the second substrate 20. The logic circuit 32, a DAC, the analog transistor (excluding the input current controller 34H) included in the signal processing circuit 34, a storage unit, and any other component are disposed in the third substrate 30.

In the imaging device 1H, as with the foregoing embodiment, the analog transistor is disposed in the second substrate 20, which makes it possible to increase the occupied area of the analog transistor and reduce noise without decreasing the occupied area of the photodiode. Moreover, disposing the analog transistor in the second substrate 20 allows for a configuration in which the analog transistor is not provided in the third substrate 30. This makes it possible to manufacture the third substrate 30 at low cost in a short process.

### Modification Example I

An imaging device 1I as a modification example I is of the column ADC type. In the imaging devices 1E to 1H, mixture of high voltage-driven transistors and low voltage-driven transistors of the analog transistors are disposed in the second substrate 20 and the third substrate 30; however, the high voltage-driven transistors and the low voltage-driven transistors may be separated to be disposed in the second substrate 20 and the third substrate 30.

In the imaging device 1I, as with the imaging device 1E, the sensor pixels 12 are disposed in the first substrate 10. The imaging device 1I includes the first signal processing circuit 22A similar to that in FIG. 11A. The amplification transistor AMP, the reset transistor RST, the select transistor SEL, and the load transistor included in the first signal processing circuit 22A are disposed in the second substrate 20.

FIG. 15 illustrates an example of the signal processing circuit 34 coupled to the stage subsequent to the vertical signal line 24. The signal processing circuit 34 includes an A/D converter. The A/D converter includes a differential input circuit. The differential input circuit of the imaging device 1I is of an NMOS input type. A ramp waveform is inputted to the reference signal input transistor. A circuit 341 including the NMOS transistor and the PMOS transistor encircled by a broken line in FIG. 15 is disposed in the second substrate 20, as with the first signal processing circuit 22A. Thus, in addition to the amplification transistor, the analog transistor included in a portion of the differential input circuit that is included in the A/D converter is disposed in the second substrate 20. In the imaging device 1I, the circuit 341 corresponds to the differential input circuit. Another high voltage-driven transistor is further disposed in the second substrate 20. In contrast, a circuit including only a low voltage-driven transistor such as the logic circuit 32, the storage unit, and any other component are disposed in the third substrate 30.

In the imaging device 1I, as with the foregoing embodiment, the analog transistor disposed in the second substrate 20, which makes it possible to increase the occupied area of the analog transistor and reduce noise without decreasing the occupied area of the photodiode. Moreover, it is not necessary to dispose the high voltage-driven transistor in the third substrate, which makes it possible to achieve a shorter process and lower cost.

### Modification Example J

An imaging device 1J as a modification example J is of the column ADC type. FIGS. 16 and 17 each illustrate an example of a cross-sectional configuration in the horizontal direction of the imaging device 1J. The imaging device 1J is an modification example of the configuration in which one first signal processing circuit is shared among four pixels in any of the imaging devices 1E to 1I. An upper diagram in each of FIGS. 16 and 17 illustrates an example of a cross section corresponding to a cross-sectional configuration taken along a cross section Sect in FIG. 4, and a lower diagram in each of FIGS. 16 and 17 illustrates an example of a cross section corresponding to a cross-sectional configuration taken along a cross section Sec2 in FIG. 4. FIG. 16 exemplifies a configuration in which two groups of 2×2, that is, four sensor pixels 12 are disposed side by side along a second direction H, and FIG. 17 exemplifies a configuration in which four groups of 2×2, that is, four sensor pixels 12 are disposed side by side along a first direction V and the second direction H. It is to be noted that in the upper cross-sectional diagrams in FIGS. 16 and 17, a diagram illustrating an example of a surface configuration of the semiconductor substrate 11 is superposed on a diagram illustrating an example of the cross-sectional configuration taken along the cross section Sec1 in FIG. 4, and the insulation layer 46 is not illustrated. Moreover, in the lower cross-sectional diagrams in FIGS. 16 and 17, a diagram illustrating an example of a surface configuration of the semiconductor substrate 21 is superposed on a diagram illustrating an example of the cross-sectional configuration taken along the cross-section Sec2 in FIG. 4. It is to be noted that in the imaging device 1J, the first signal processing circuit 22A includes the amplification transistor AMP, the reset transistor RST, and the select transistor SEL. In the imaging device 1J, the analog transistor included in the first signal processing circuit 22A is disposed in the second substrate 20. With regard to the A/D converter coupled to a stage subsequent to the readout circuit 22 including the first signal processing circuit 22A, in addition to the amplification transistor, the analog transistor included in a portion of the A/D converter is disposed in the second substrate 20.

As illustrated in FIG. 16, a plurality of through wiring lines 54, a plurality of through wiring lines 48, and a plurality of through wiring lines 47 are disposed side by side in a band-like fashion along the first direction V (in a upward-downward direction in FIG. 16) in a plane of the first substrate 10. It is to be noted that FIG. 16 exemplifies a case where the plurality of through wiring lines 54, the plurality of through wiring lines 48, and the plurality of through wiring lines 47 are disposed side by side in two columns along the first direction V. Moreover, as illustrated in FIG. 17, the plurality of through wiring lines 54, the plurality of through wiring lines 48, the plurality of through wiring lines 47 are disposed side by side in a band-like fashion along the second direction H (a rightward-leftward direction in FIG. 17) in the plane of the first substrate 10. It is to be noted that FIG. 17 illustrates an example in which the plurality of through wiring lines 54, the plurality of through wiring lines 48, and the plurality of through wiring lines 47 are disposed side by side in two columns along the second direction H. The first direction V is parallel to an arrangement direction (for example, a column direction) of two arrangement directions (for example, a row direction and the column direction) of the plurality of sensor pixels 12 arranged in a matrix. In four sensor pixels 12 among which the first signal processing circuit 22A is shared, four floating diffusion FD are disposed close to one another with the element separator 43 interposed therebetween, for example. In the four sensor pixels among which the first signal processing circuit 22A is shared, four transfer gate electrodes TG are disposed to surround the four floating diffusions FD, and form an annular shape, for example.

The insulation layer 53 includes a plurality of blocks extending along the first direction V. The semiconductor substrate 21 includes a plurality of island-shaped blocks 21A that extend along the first direction V and are disposed side by side along the second direction H orthogonal to the first direction V with the insulation layer 53 interposed therebetween. Each of the blocks 21A includes, for example, a plurality of groups of the reset transistor RST, the amplification transistor AMP, and the select transistor SEL. One first signal processing circuit 22A shared among four sensor pixels 12 includes the reset transistor RST, the amplification transistor AMP, and the select transistor SEL that are disposed in a region opposed to the four sensor pixels 12, for example. One readout circuit 22 shared among four sensor pixels 12 includes, for example, the amplification transistor in the block 21A on the left of the insulation layer 53, and the reset transistor RST and the select transistor SEL in the block 21A on the right of the insulation layer 53.

FIGS. 18, 19, 20, and 21 each illustrate an example of a wiring layout in a horizontal plane of the imaging device 1J as the modification example J. FIGS. 18 to 21 each illustrate an example in which one first signal processing circuit 22A shared among four sensor pixels 12 is provided in a region opposed to the four sensor pixels 12. Wiring lines illustrated in FIGS. 18 to 21 are provided in layers different from one another in the wiring layer 56, for example.

Four through wiring lines 54 adjacent to one another are electrically coupled to the coupling wiring line 55, for example, as illustrated in FIG. 18. The four through wiring lines 54 adjacent to one another are further electrically coupled to the gate of the amplification transistor AMP included in the block 21A on the left of the insulation layer 53 and a gate of the reset transistor RST included in the block 21A on the right of the insulation layer 53 through the coupling wiring line 55 and the coupling sections 59, for example, as illustrated in FIG. 18.

The power source line VDD is disposed at a position opposed to each of the first signal processing circuits 22A disposed side by side along the second direction H, for example, as illustrated in FIG. 19. The power source line VDD is electrically coupled to the drain of the amplification transistor AMP and the drain of the reset transistor RST in each of the first signal processing circuits 22A disposed side by side along the second direction H through the coupling sections 59, for example, as illustrated in FIG. 19. Two pixel drive lines 23 each are disposed at a position opposed to the readout circuits 22 disposed side by side along the second direction H, for example, as illustrated in FIG. 19. One (a second control line) of the two pixel drive lines 23 is, for example, a wiring line RSTG electrically coupled to the gate of the reset transistor RST of each of the readout circuits 22 disposed side by side along the second direction H, as illustrated in FIG. 19. The other (a third control line) is, for example, a wiring line SELG electrically coupled to a gate of the select transistor SEL of each of the readout circuits 22 disposed side by side along the second direction H, as illustrated in FIG. 19. In each of the first signal processing circuits 22A, a source of the amplification transistor AMP and a drain of the select transistor SEL are electrically coupled to each other through the wiring line 25, for example, as illustrated in FIG. 19.

Two power source lines VSS each are disposed at a position opposed to the first signal processing circuits 22A disposed side by side along the second direction H, for example, as illustrated in FIG. 20. Each of the power source lines VSS is electrically coupled to the plurality of through wiring lines 47 at a position opposed to the sensor pixels 12 disposed side by side along the second direction H. Four pixel drive lines 23 each are disposed at a position opposed to the first signal processing circuits 22A disposed side by side along the second direction H, for example, as illustrated in FIG. 20. Each of the four pixel drive lines 23 is, for example, a wiring line TRG electrically coupled to the through wiring line 48 of one sensor pixel 12 of the four sensor pixels 12 corresponding to a corresponding one of the first signal processing circuits 22A disposed side by side along the second direction H, as illustrated in FIG. 20. In other words, the four pixel drive lines 23 (first control lines) are electrically coupled to the gates (the transfer gate electrodes TG) of the transfer transistors TX of the sensor pixels 12 disposed side by side along the second direction H. In FIG. 20, in order to discriminate the respective wiring lines TRG, identifiers (1, 2, 3, and 4) are given to ends of the respective wiring lines TRG.

The vertical signal line 24 is disposed at a position opposed to the first signal processing circuits 22A disposed side by side along the first direction V, for example, as illustrated in FIG. 21. The vertical signal line 24 (an output line) is electrically coupled to an output terminal (the source of the amplification transistor AMP) of each of the readout circuits 22 disposed side by side along the first direction V, for example, as illustrated in FIG. 21.

### Modification Example K

FIG. 22 illustrates an example of a cross-sectional configuration in the vertical direction of an imaging device 1K as a modification example K. The imaging device 1K is an modification example of the imaging device 1 according to the foregoing embodiment. In the imaging device 1K, the transfer transistor TX includes a flat type transfer gate electrode TG. Accordingly, the transfer gate electrode TG does not penetrate through the well layer 42, and is provided only on the front surface of the semiconductor substrate 11. Even in a case where the transfer transistor TX uses the flat type transfer gate electrode TG, the imaging device 1K has effects similar to those in the foregoing embodiment. It is to be noted that in FIG. 22, as the first signal processing circuit 22A, one transistor is illustrated as a representative of the amplification transistor AMP, the reference signal input transistor REF, and the current source transistor Vb. In the imaging device 1K, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

Modification Example L

FIG. 23 illustrates an example of a cross-sectional configuration in the vertical direction of an imaging device 1L as a modification example L. The imaging device 1L is a modification example of the imaging device 1 according to the foregoing embodiment. In the imaging device 1L, electrical coupling between the second substrate 20 and the third substrate 30 are made in a region opposed to a peripheral region 14 of the first substrate 10. The peripheral region 14 corresponds to a frame region of the first substrate 10, and is provided at an outer edge of the pixel region 13. In the imaging device 1L, the second substrate 20 includes a plurality of pad electrodes 58 in a region opposed to the peripheral region 14, and the third substrate 30 includes a plurality of pad electrodes 64 in a region opposed to the peripheral region 14. The second substrate 20 and the third substrate 30 are electrically coupled to each other by bonding between the pad electrodes 58 provided in the region opposed to the peripheral region 14 and the pad electrodes 64 provided in the region opposed to the peripheral region 14. It is to be noted that in FIG. 23, as the first signal processing circuit 22A, one transistor is illustrated as a representative of the amplification transistor AMP, the reference signal input transistor REF, and the current source transistor Vb. In the imaging device 1L, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

As described above, in the imaging device 1L, the second substrate 20 and the third substrate 30 are electrically coupled to each other by bonding between the pad electrodes 58 provided in the region opposed to the peripheral region 14 and the pad electrode 64 provided in the region opposed to the peripheral region 14. This makes it possible to reduce a possibility of impairing reduction in area per pixel, as compared to a case where the pad electrodes 58 and 64 are bonded together in a region opposed to the pixel region 13. Accordingly, it is possible to provide the imaging device 1L having a three-layer configuration having a substantially same chip size as before without impairing reduction in area per pixel.

### Modification Example M

An imaging device 1M as a modification example M is of the column ADC type. FIGS. 24 and 25 each illustrate an example of a cross-sectional configuration in the horizontal direction of the imaging device 1M. The imaging device 1M is a modification example of the configuration in which one first signal processing circuit is shared among four pixels in any of the imaging devices 1E to 1I. An upper diagram in each of FIGS. 24 and 25 illustrates a modification example of the cross section corresponding to the cross-sectional configuration taken along the cross section Sec1 in FIG. 4, and a lower diagram in each of FIGS. 24 and 25 illustrates a modification example of the cross section corresponding to the cross-sectional configuration taken along the cross section Sec2 in FIG. 4. It is to be noted that in the upper cross-sectional diagrams in FIGS. 24 and 25, a diagram illustrating a modification example of the surface configuration of the semiconductor substrate 11 is superposed on a diagram illustrating a modification example of the cross-sectional configuration taken along the cross section Sec1 in FIG. 4, and the insulation layer 46 is not illustrated. Moreover, in the lower cross-sectional diagrams in FIGS. 24 and 25, a diagram illustrating a modification example of the surface configuration of the semiconductor substrate 21 is superposed on a diagram illustrating a modification example of the cross-sectional configuration taken along the cross-section Sec2 in FIG. 4. It is to be noted that in the example in FIG. 24, the first signal processing circuit 22A includes, for example, the amplification transistor AMP, the reset transistor RST, and the select transistor SEL. Moreover, in the example in FIG. 25, the first signal processing circuit 22A includes, for example, the amplification transistor AMP, the reset transistor RST, the select transistor SEL, and the FD transfer transistor FDG. In the imaging device 1M, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

As illustrated in FIGS. 24 and 25, a plurality of through wiring lines 54, a plurality of through wiring lines 48, and a plurality of through wiring lines 47 (a plurality of dots disposed in rows and columns in the diagrams) are disposed side by side in a band-like fashion along the second direction H (in the rightward-leftward direction in FIGS. 24 and 25) in a plane of the first substrate 10. It is to be noted that FIGS. 24 and FIG. 25 each exemplify a case where the plurality of through wiring lines 54, the plurality of through wiring lines 48, and the plurality of through wiring lines 47 are disposed side by side in two columns along the second direction H. In four sensor pixels 12 among which the first signal processing circuit 22A is shared, four floating diffusions FD are disposed close to one another with the element separator 43 interposed therebetween, for example. In the four sensor pixels 12 among which the first signal processing circuit 22A is shared, four transfer gate electrodes TG (TG1, TG2, TG3, and TG4) are disposed to surround the four floating diffusions FD, and form an annular shape, for example.

The insulation layer 53 includes a plurality of blocks extending along the second direction H. The semiconductor substrate 21 includes a plurality of island-shaped blocks 21A that extend along the second direction H and are disposed side by side along the first direction V orthogonal to the second direction H with the insulation layer 53 interposed therebetween. Each of the blocks 21A includes, for example, the reset transistor RST, the amplification transistor AMP, and the select transistor SEL. One first signal processing circuit 22A shared among four sensor pixels 12 does not face the four sensor pixels 12, for example, and is shifted toward the first direction V.

In FIG. 24, one first signal processing circuit 22A shared among four sensor pixels 12 includes the reset transistor RST, the amplification transistor AMP, and the select transistor SEL in a region shifted toward the first direction V from a region opposed to the four sensor pixels 12 in the second substrate 20. The one first signal processing circuit 22A shared among four sensor pixels 12 includes, for example, the amplification transistor AMP, the reset transistor RST, and the select transistor SEL in one block 21A.

In FIG. 25, one first signal processing circuit 22A shared among four sensor pixels 12 includes the reset transistor RST, the amplification transistor AMP, the select transistor SEL, and the FD transfer transistor FDG in a region shifted toward the first direction V from a region opposed to the four sensor pixels 12 in the second substrate 20. The one first signal processing circuit 22A shared among four sensor pixels 12 includes, for example, the amplification transistor AMP, the reset transistor RST, the select transistor SEL, and the FD transfer transistor FDG in one block 21A.

In the imaging device 1M, one first signal processing circuit 22A shared among four sensor pixels 12 does not face the four sensor pixels 12, for example, and is shifted toward the first direction V from a position facing the four sensor pixels 12. In such a case, it is possible to shorten the wiring line 25, or to omit the wiring line 25, thereby allowing an impurity region to be shared between the source of the amplification transistor AMP and the drain of the select transistor SEL. As a result, it is possible to reduce the size of the first signal processing circuit 22A and increase a size of any other portion in the first signal processing circuit 22A.

### Modification Example N

An imaging device 1N as a modification example N is of the column ADC type. FIG. 26 illustrates an example of a cross-sectional configuration in the horizontal direction of the imaging device 1N as the modification example N. The imaging device 1N is a modification example of the imaging device 1J. FIG. 26 illustrates a modification example of the cross-sectional configuration in FIG. 16. It is to be noted that in the example in FIG. 26, the first signal processing circuit 22A includes, for example, the amplification transistor AMP, the reset transistor RST, and the select transistor SEL. In the imaging device 1N, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

In the imaging device 1N, the semiconductor substrate 21 includes a plurality of island-shaped blocks 21A disposed side by side along the first direction V and the second direction H with the insulation layer 53 interposed therebetween. Each of the blocks 21A includes, for example, a group of the reset transistor RST, the amplification transistor AMP, and the select transistor SEL. Such a case makes it possible to suppress crosstalk between adjacent readout circuits 22 by the insulation layer 53 and suppress reduction in resolution on a regenerated image and deterioration in image quality caused by color mixture.

### Modification Example O

An imaging device 10 as a modification example O is of the column ADC type. FIG. 27 illustrates an example of a cross-sectional configuration in the horizontal direction of the imaging device 10 as the modification example O. The imaging device 10 is a modification example of the imaging device 1N. FIG. 27 illustrates a modification example of the cross-sectional configuration in FIG. 26. It is to be noted that in the example in FIG. 27, the first signal processing circuit 22A includes, for example, the amplification transistor AMP, the reset transistor RST, and the select transistor SEL. In the imaging device 10, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

In the imaging device 10, one first signal processing circuit 22A shared among four sensor pixels 12 does not face the four sensor pixels 12, for example, and is shifted toward the first direction V. Moreover, in the imaging device 10, as with the imaging device 1N, the semiconductor substrate 21 includes a plurality of island-shaped blocks 21A disposed side by side along the first direction V and the second direction H with the insulation layer 53 interposed therebetween. Each of the blocks 21A includes, for example, a group of the reset transistor RST, the amplification transistor AMP, and the select transistor SEL. Moreover, in the imaging device 10, a plurality of through wiring lines 47 and a plurality of through wiring lines 54 are disposed side by side also along the second direction H. Specifically, the plurality of through wiring lines 47 are disposed between four through wiring lines 54 among which a certain first signal processing circuit 22A is shared and four through wiring lines 54 among which another first signal processing circuit 22A adjacent in the second direction H to the certain first signal processing circuit 22A is shared. Such a case makes it possible to suppress crosstalk between adjacent first signal processing circuits 22A by the insulation layer 53 and the through wiring lines 47 and suppress reduction in resolution on a regenerated image and deterioration in image quality caused by color mixture.

### Modification Example P

An imaging device 1P as a modification example P is of the column ADC type. FIG. 28 illustrates an example of a cross-sectional configuration in the horizontal direction of the imaging device 1P as the modification example P. The imaging device 1P is a modification example of the imaging device 1J. FIG. 28 illustrates a modification example of the cross-sectional configuration in FIG. 16. It is to be noted that in the example in FIG. 28, the first signal processing circuit 22A includes, for example, the amplification transistor AMP, the reset transistor RST, and the select transistor SEL. In the imaging device 1P, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

In the imaging device 1P, the first substrate 10 includes the photodiode PD and the transfer transistor TX in each of the sensor pixels 12, and one floating diffusions FD is shared among every four sensor pixels 12. Accordingly, in the imaging device 1P, one through wiring line 54 is provided for every four sensor pixels 12.

In the plurality of sensor pixels arranged in a matrix, four sensor pixels 12 corresponding to a region obtained through shifting, by one sensor pixel 12 toward the first direction V, a unit region corresponding to four sensor pixels 12 among which one floating diffusion FD is shared are referred to as “four sensor pixels 12A” for the sake of convenience. On this occasion, in the imaging device 1P, one through wiring line 47 is shared among every four sensor pixels 12A in the first substrate 10. Accordingly, in the imaging device 1P, one through wiring lines 47 is provided for every four sensor pixels 12A.

In the imaging device 1P, the first substrate 10 includes the element separator 43 that separates the photodiodes PD and the transfer transistors TX for each of the sensor pixels 12. The element separator 43 does not completely encircle the sensor pixel 12 as viewed from the direction of the normal to the semiconductor substrate 11, and has gaps (non-formation regions) near the floating diffusion FD (the through wiring line 54) and near the through wiring line 47. The gaps allow for sharing of one through wiring line 54 among four sensor pixel 12 and sharing of one through wiring line 47 among four sensor pixels 12A. In the imaging device 1P, the second substrate 20 includes the first signal processing circuit 22A for every four sensor pixels 12 among which the floating diffusion FD is shared.

### Modification Example Q

An imaging device 1Q as a modification example Q is of the column ADC type. FIG. 29 illustrates an example of a cross-sectional configuration in the horizontal direction of the imaging device 1Q as the modification example Q. The imaging device 1Q is a modification example of the imaging device 1N. FIG. 29 illustrates a modification example of the cross-sectional configuration in FIG. 26. It is to be noted that in the example in FIG. 29, the first signal processing circuit 22A includes, for example, the amplification transistor AMP, the reset transistor RST, and the select transistor SEL. In the imaging device 1Q, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

In the imaging device 1Q, the first substrate 10 includes the photodiode PD and the transfer transistor TX for each of the sensor pixels 1, and one floating diffusion FD is shared among every four sensor pixels 12. Moreover, the first substrate 10 includes the element separator 43 that separates the photodiodes PD and the transfer transistors TX for each of the sensor pixels 12.

### Modification Example R

An imaging device 1R as a modification example R is of the column ADC type. FIG. 30 illustrates an example of a cross-sectional configuration in the horizontal direction of the imaging device 1R as the modification example R. The imaging device 1R is a modification example of the imaging device 10. FIG. 30 illustrates a modification example of the cross-sectional configuration in FIG. 27. It is to be noted that in the example in FIG. 30, the first signal processing circuit 22A includes, for example, the amplification transistor AMP, the reset transistor RST, and the select transistor SEL. In the imaging device 1R, the analog transistor included in the first signal processing circuit 22A is disposed in the second substrate 20. Moreover, with regard to the A/D converter coupled to the stage subsequent to the readout circuit 22 including the first signal processing circuit 22A, in addition to the amplification transistor, the analog transistor included in a portion of the A/D converter is disposed in the second substrate 20.

In the imaging device 1R, the first substrate 10 includes the photodiode PD and the transfer transistor TX for each of the sensor pixels 12, and one floating diffusion FD is shared among every four sensor pixels 12. Moreover, the first substrate 10 includes the element separator 43 that separates the photodiodes PD and the transfer transistors TX for each of the sensor pixels 12.

### Modification Example S

FIG. 31 illustrates an example of a circuit configuration of an imaging device 1S as a modification example S. The imaging device 1S is a modification example of any of the foregoing imaging devices 1 and 1A to 1R. The imaging device 1S includes a CMOS image sensor including a column parallel ADC.

As illustrated in FIG. 31, the imaging device 1S includes the vertical drive circuit 33, the signal processing circuit 34, a reference voltage supply unit 38, the horizontal drive circuit 35, a horizontal output line 37, and the system control circuit 36, in addition to the pixel region 13 in which the plurality of sensor pixels 12 each including a photo-electric converter are two-dimensionally arranged in rows and columns, i.e., in a matrix.

In this system configuration, the system control circuit 36 generates a clock signal, a control signal, and any other signal serving as references of operations of the vertical drive circuit 33, the signal processing circuit 34, the reference voltage supply unit 38, the horizontal drive circuit 35, and any other component on the basis of a master clock MCK, and supplies such signals to the vertical drive circuit 33, the signal processing circuit 34, the reference voltage supply unit 38, the horizontal drive circuit 35, and any other component.

Moreover, the vertical drive circuit 33 is provided, together with the respective sensor pixels 12 in the pixel region 13, in the first substrate 10, and is also provided in the second substrate 20 in which the first signal processing circuit 22A included in the readout circuit 22 is provided. The signal processing circuit 34, the reference voltage supply unit 38, the horizontal drive circuit 35, the horizontal output line 37, and the system control circuit 36 are provided in the third substrate 30.

Although not illustrated, the sensor pixels 12 may use, for example, a configuration including, in addition to the photodiode PD, the transfer transistor TX that transfers, to the floating diffusion FD, a charge obtained by photoelectric conversion in the photodiode PD. Moreover, although not illustrated, the readout circuit 22 may use, for example, a three-transistor configuration including the reset transistor RST that controls the potential of the floating diffusion FD, the amplification transistor AMP that outputs a signal corresponding to the potential of the floating diffusion FP, and the select transistor SEL for pixel selection.

In the pixel region 13, the sensor pixels 12 are two-dimensionally arranged, and one of the pixel drive lines 23 are wired with each of rows of an m-row by n-column pixel arrangement, and one of the vertical signal lines 24 is wired with each of columns of the m-row by n-column pixel arrangement. The plurality of pixel drive lines 23 each have one end coupled to a corresponding one of output terminals, corresponding to the respective rows, of the vertical drive circuit 33. The vertical drive circuit 33 includes a shift register and any other component, and performs control of a row address and row scanning of the pixel region 13 through the plurality of pixel drive lines 23.

The signal processing circuit 34 includes, for example, analog-to-digital conversion circuits (ADCs) 34-1 to 34-m, one of which is provided for each of pixel columns of the pixel region 13, i.e., for each of the vertical signal lines 24, and converts an analog signal outputted from each of columns of the sensor pixels 12 in the pixel region 13 into a digital signal, and outputs the digital signal. It is to be noted that as described in the foregoing embodiment, the ADC may be provided for each of the sensor pixels 12.

The reference voltage supply unit 38 includes, for example, a digital-to-analog conversion circuit (DAC) 38A as a means of generating a reference voltage Vref of a so-called ramp waveform, of which a level varies gradiently with time. It is to be noted that the means of generating the reference voltage Vref of the ramp waveform is not limited to the DAC 38A.

The DAC 38A generates the reference voltage Vref of the ramp waveform on the basis of a clock CK supplied from the system control circuit 36 under control by a control signal CS1 supplied from the system control circuit 36, and supplies the reference voltage Vref to the ADCs 34-1 to 34-m of a column processor.

It is to be noted that each of the ADCs 34-1 and 34-m is allowed to selectively perform an A/D conversion operation corresponding to each of operation modes. The operation modes include a normal frame rate mode in a progressive scanning system in which information of all the sensor pixels 12 is read, and a high frame rate mode in which an exposure time of the sensor pixels 12 is set to 1/N to increase a frame rate by N times, for example, twice the frame rate in the normal frame rate mode. Such switching of the operation modes is executed by control by control signals CS2 and CS3 supplied from the system control circuit 36. Moreover, instruction information for switching between the operation modes, i.e., the normal frame rate mode and the high frame rate mode is provided from an unillustrated external system controller to the system control circuit 36.

The ADCs 34-1 to 34-m all have the same configuration, and herein, the ADC 34-m is described as an example. The ADC 34-m includes, for example, a comparator 34A, an up-down counter (which is referred to as “U/DCNT” in the drawing) 34B serving as a counting means, a transfer switch 34C, and a memory device 34D.

The comparator 34A compares a signal voltage Vx of the vertical signal line 24 corresponding to a signal outputted from each of the sensor pixels 12 in a n-th column of the pixel region 13 with the reference voltage Vref of the ramp waveform supplied from the reference voltage supply unit 38, and turns an output Vco to an “H” level in a case where the reference voltage Vref is larger than the signal voltage Vx, for example, and turns the output Vco to an “L” level in a case where the reference voltage Vref is equal to or smaller than the signal voltage Vx, for example.

The up-down counter 34B includes an asynchronous counter, and measures a comparison period from the start to the end of the comparison operation in the comparator 34A through receiving the clock CK from the system control circuit 36 simultaneously with the DAC 38A and performing down-counting or up-counting in synchronization with the clock CK under control by the control signal CS2 supplied from the system control circuit 36.

Specifically, in the normal frame rate mode, in an operation of reading a signal from one sensor pixel 12, a comparison time in first readout is measured through performing down-counting in a first readout operation, and a comparison time in second readout is measured through performing up-counting in a second readout operation.

In contrast, in the high frame rate mode, a counting result of the sensor pixels 12 in a certain row is kept as it is. Subsequently, for the sensor pixels 12 in a row subsequent to the certain row, the comparison time in the first readout is measured through performing down-counting in the first readout operation from the previous counting result, and the comparison time in the second readout is measured through performing up-counting in the second readout operation.

In the normal frame rate mode, under control by the control signal CS3 supplied from the system control circuit 36, the transfer switch 34C is turned to an ON (closed) state when the counting operation for the sensor pixels 12 in the certain row by the up-down counter 34B is completed, and transfers a counting result by the up-down counter 34B to the memory device 34D.

In contrast, at a high frame rate of N=2, the transfer switch 34C remains in an OFF (open) state when the counting operation for the sensor pixels 12 in the certain row by the up-down counter 34B is completed. Subsequently the transfer switch 34C is turned to the ON state when the counting operation for the sensor pixels 12 in the row subsequent to the certain row by the up-down counter 34B is completed, and transfers counting results of two vertical pixels by the up-down counter 34B to the memory device 34D.

As described above, analog signals supplied from the sensor pixels 12 in the pixel region 13 on a column-by-column basis through the vertical signal lines 24 are converted into N-bit digital signals by the respective operations by the comparator 34A and the up-down counter 34B in the ADCs 34-1 to 34-m, and the digital signals are stored in the memory devices 34D.

The horizontal drive circuit 35 includes a shift register and any other component, and performs control of column addresses and column scanning of the ADCs 34-1 to 34-m in the signal processing circuit 34. Under control by the horizontal drive circuit 35, the N-bit digital signals obtained by A/D conversion in the respective ADCs 34-1 to 34-m are sequentially read to the horizontal output line 37, and are outputted as imaging data through the horizontal output line 37.

It is to be noted that a circuit and any other component that perform various kinds of signal processing on imaging data outputted through the horizontal output line 37 may be provided in addition to the components described above; however, the circuit and the other components are not illustrated, because the circuit and the other components are not directly related to the present disclosure.

In the imaging device 1S including the column parallel ADC that has the foregoing configuration, it is possible to selectively transfer the counting result from the up-down counter 34B to the memory device 34D through the transfer switch 34C, which makes it possible to independently control the counting operation by the up-down counter 34B and the readout operation of the counting result from the up-down counter 34B to the horizontal output line 37.

### Modification Example T

FIG. 32 illustrates an example of a configuration of an imaging device 1T as a modification example T. The imaging device 1T is a modification example of any of the foregoing imaging devices 1 and 1A to 1S. In the imaging device 1T, the first substrate 10 includes the pixel region 13 including the plurality of sensor pixels 12 that is provided in a central portion, and the vertical drive circuit 33 that is provided around the pixel region 13. Moreover, in the second substrate 20, a readout circuit region 15 including the plurality of first signal processing circuits 22A is provided in a central portion, and the vertical drive circuit 33 is provided around the readout circuit region 15. In the third substrate 30, the signal processing circuit 34, the horizontal drive circuit 35, the system control circuit 36, the horizontal output line 37, and the reference voltage supply unit 38 are provided. As with the foregoing embodiment and the modification examples thereof, this prevents an increase in chip size and impairment of reduction in area per pixel resulting from a configuration in which substrates are electrically coupled to each other. As a result, it is possible to provide the imaging device 1 having a three-layer configuration that has a substantially same chip size as before without impairing reduction in area per pixel. It is to be noted that the vertical drive circuit 33 may be provided only in the first substrate 10, or may be provided only in the second substrate 20.

### Modification Example U

FIG. 33 illustrates an example of a configuration of an imaging device 1U as a modification example U. The imaging device 1U is a modification example of any of the foregoing imaging devices 1 and 1A to 1T. Each of the foregoing imaging devices 1 and 1A to 1T is configured through stacking three substrates (the first substrate 10, the second substrate 20, and the third substrate 30). However, each of the foregoing imaging devices 1 and 1A to 1T may be configured through stacking two substrates (the first substrate 10 and the second substrate 20). On this occasion, the logic circuit 32 is separated to be provided for the first substrate 10 and the second substrate 20, for example, as illustrated in FIG. 33. Herein, a circuit 32A provided in the first substrate 10 of the logic circuit 32 includes a transistor having a gate configuration in which a high-dielectric film including a material resistant to a high-temperature process (for example, a high-k material) and a metal gate electrode are stacked. In contrast, in a circuit 32B provided in the second substrate 20, a low-resistance region 26 including a silicide such as CoSi₂ and NiSi is provided on a front surface of an impurity diffusion region in contact with a source electrode and a drain electrode. The silicide is prepared with use of a self aligned silicide (salicide) process. The low-resistance region including the silicide includes a compound containing a material of the semiconductor substrate and a metal. This makes it possible to use a high-temperature process such as thermal oxidation for formation of the sensor pixels 12. Moreover, it is possible to reduce contact resistance in a case where the low-resistance region 26 including the silicide is provided on the front surface of the impurity diffusion region in contact with the source electrode and the drain electrode in the circuit 32B provided in the second electrode 20 of the logic circuit 32. As a result, it is possible to increase operation speed of the logic circuit 32.

### Modification Example V

FIG. 34 illustrates an example of a configuration of an imaging device 1V as a modification example V. The imaging device 1V is a modification example of any of the foregoing imaging devices 1 and 1A to 1T. In the logic circuit 32 of the third substrate 30 in any of the foregoing imaging devices 1 and 1A to 1T, a low-resistance region 37A including a silicide such as CoSi₂ and NiSi may be provided on the front surface of the impurity diffusion region in contact with the source electrode and the drain electrode. The silicide is prepared with use of a self aligned silicide (salicide) process. This makes it possible to use a high-temperature process such as thermal oxidation for formation of the sensor pixels 12. Moreover, it is possible to reduce contact resistance in a case where the low-resistance region 37A including the silicide is provided on the front surface of the impurity diffusion region in contact with the source electrode and the drain electrode in the logic circuit 32. As a result, it is possible to increase operation speed of the logic circuit 32.

### Modification Example W

In the foregoing imaging devices 1 and 1A to 1V, the conductivity types may be reversed. For example, in the foregoing embodiment and the modification examples A to V, the p-type may be replaced with the n-type, and the n-type may be replaced with the p-type. Even in such a case, effects similar to those in the foregoing imaging devices 1 and 1A to 1V are achievable.

### 3. APPLICATION EXAMPLES

### Application Example 1

The foregoing imaging devices 1 and 1A to 1W (hereinafter referred to as “imaging device 1” as a representative) are applicable to various types of electronic apparatuses. Non-limiting examples of the electronic apparatuses include a camera such as a digital still camera and a digital video camera, a mobile phone having an imaging function, and any other device having an imaging function.

FIG. 35 is a block diagram illustrating an example of a schematic configuration of an electronic apparatus including the imaging device 1 according to any of the foregoing embodiment and the modification examples thereof.

An electronic apparatus 201 illustrated in FIG. 35 includes an optical system 202, a shutter device 203, the imaging device 1, a control circuit 205, a signal processing circuit 206, a monitor 207, and a memory 208, and is capable of imaging a still image and a moving image.

The optical system 202 includes one or more lenses, and guides light (incident light) from an object to the imaging device 1 and forms an image on a light reception surface of the imaging device 1.

The shutter device 203 is disposed between the optical system 202 and the imaging device 1, and controls a period in which the imaging device 1 is irradiated with the light and a period in which the light is blocked in accordance with control by the control circuit 205.

The imaging device 1 includes a package including the foregoing imaging device. The imaging device 1 accumulates signal charges for a certain period in accordance with light of which an image is formed on the light reception surface through the optical system 202 and the shutter device 203. The signal charges accumulated in the imaging device 1 are transferred in accordance with a drive signal (a timing signal) supplied from the control circuit 205.

The control circuit 205 outputs the drive signal that controls a transfer operation of the imaging device 1 and a shutter operation of the shutter device 203 to drive the imaging device 1 and the shutter device 203.

The signal processing circuit 206 performs various types of signal processing on signal charges outputted from the imaging device 1. An image (image data) obtained through performing the signal processing by the signal processing circuit 206 is supplied to the monitor 207 to be displayed, or is supplied to the memory 208 to be stored (recorded).

In the electronic apparatus 201 as configured above, application of the imaging device 1 makes it possible to achieve imaging having reduced noise in all pixels.

### Application Example 2

FIG. 36 illustrates an example of a schematic configuration of an imaging system 2 including any of the foregoing imaging devices 1 and 1A to 1W. FIG. 36 illustrates the imaging device 1 as a representative of the imaging devices 1 and 1A to 1W. Hereinafter, the imaging devices 1 and 1A to 1W are referred to as “imaging device 1” as a representative.

The imaging system 2 includes, for example, an electronic apparatus. Non-limiting examples of the electronic apparatus includes an imaging apparatus such as a digital still camera and a video camera, and a mobile terminal such as a smartphone and a tablet terminal. The imaging system 2 includes, for example, the imaging device 1 according to any of the foregoing embodiment and the modification examples thereof, a DSP circuit 141, a frame memory 142, a display unit 143, a storage unit 144, an operation unit 145, and a power source unit 146. In the imaging system 2, the imaging device 1 according to any of the foregoing embodiment and the modification examples thereof, the DSP circuit 141, the frame memory 142, the display unit 143, the storage unit 144, the operation unit 145, and the power source unit 146 are coupled to one another through a bus line 147.

The imaging device 1 according to any of the foregoing embodiment and the modification examples thereof outputs image data corresponding to incident light. The DSP circuit 141 includes a signal processing circuit that performs processing on a signal (image data) outputted from the imaging device 1 according to any of the foregoing embodiment and the modification examples A to W. The frame memory 142 temporarily holds the image data processed by the DSP circuit 141 in a frame unit. The display unit 143 includes, for example, a panel type display device such as a liquid crystal panel and an organic electroluminescence (EL) panel, and displays a moving image or a still image taken by the imaging device 1 according to any of the foregoing embodiment and the modification examples thereof. The storage unit 144 stores, in a storage medium such as a semiconductor memory and a hard disk, the image data such as the moving image or the still image taken by the imaging device 1 according to any of the foregoing embodiment and the modification examples thereof. The operation unit 145 provides an operation instruction about various kinds of functions of the imaging system 2 in accordance with an operation by a user. The power source unit 146 supplies various kinds of power to the imaging device 1 according to the foregoing embodiment and the modification examples thereof, the DSP circuit 141, the frame memory 142, the display unit 143, the storage unit 144, and the operation unit 145 as necessary. The various kinds of power serve as operation power for the imaging device 1 according to any of the foregoing embodiment and the modification examples thereof, the DSP circuit 141, the frame memory 142, the display unit 143, the storage unit 144, and the operation unit 145.

Next, description is given of an imaging procedure in the imaging system 2.

FIG. 37 illustrates an example of a flow chart of an imaging operation in the imaging system 2. A user operates the operation unit 145 to provide an instruction for start of imaging (step S101). Thereafter, the operation unit 145 transmits an instruction for imaging to the imaging device 1 (step S102). The imaging device 1 (specifically, the system control circuit 36) receives the instruction for imaging, and executes imaging in a predetermined imaging system (step S103).

The imaging device 1 outputs image data obtained by imaging to the DSP circuit 141. Herein, the image data includes data of pixel signals of all pixels generated on the basis of charges temporarily stored in the floating diffusions FD. The DSP circuit 141 performs predetermined signal processing (for example, noise reduction) on the basis of the image data inputted from the imaging device 1 (step S104). The DSP circuit 141 stores the image data having been subjected to the predetermined signal processing in the frame memory 142, and the frame memory 142 stores the image data in the storage unit 144 (step S105). Thus, imaging in the imaging system 2 is performed.

In the present application example, the imaging device 1 according to any of the foregoing embodiment and the modification examples A to W is applied to the imaging system 2. This makes it possible to downsize the imaging device 1 or increase definition of the imaging device 1, thereby providing the imaging system 2 having a small size or high definition.

### FURTHER APPLICATION EXAMPLES

### Further Application Example 1

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body include an automobile, an electric vehicle, a hybrid electric vehicle, a motorcycle, a bicycle, any personal mobility device, an airplane, an unmanned aerial vehicle (drone), a vessel, and a robot.

FIG. 38 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 38, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent or reduce a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 38, an audio speaker 12061, a display section 12062, and an instrument panel 12063 are illustrated as the output device. The display section 12062 may, for example, include at least one of an on-board display and a head-up display.

FIG. 39 is a diagram depicting an example of the installation position of the imaging section 12031.

In FIG. 39, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 39 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the foregoing, the description has been given of one example of the mobile body control system, to which the technology according to an embodiment of the present disclosure is applicable. The technology according to an embodiment of the present disclosure may be applied to, for example, the imaging section 12031 among components of the configuration described above. Specifically, the imaging device 1 according to the foregoing embodiment and the modification examples thereof may be applied to the imaging section 12031. Applying the technology according to an embodiment of the present disclosure to the imaging section 12031 makes it possible to obtain a captured image having less noise and high definition. Hence, it is possible to perform high-precision control with use of the captured image in the mobile body control system.

### Further Application Example 2

FIG. 40 is a view depicting an example of a schematic configuration of an endoscopic surgery system to which the technology according to an embodiment of the present disclosure (present technology) can be applied.

In FIG. 40, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/

WO or excitation light suitable for special light observation as described above.

FIG. 41 is a block diagram depicting an example of a functional configuration of the camera head 11102 and the CCU 11201 depicted in FIG. 40.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the foregoing, the description has been given of one example of the endoscopic surgery system to which the technology according to an embodiment of the present disclosure can be applied. The technology according to an embodiment of the present disclosure may be preferably applied to the image pickup unit 11402 provided in the camera head 11102 of the endoscope 11100 among the components of the configuration described above. Applying the technology according to an embodiment of the present disclosure to the image pickup unit 11402 makes it possible to downsize the image pickup unit 11402 or increase definition of the image pickup unit 11402. Hence, it is possible to provide the endoscope 11100 having a small size or high definition.

Although the description has been given with reference to the embodiment, the modification examples A to W, the application examples, and the further application examples, the present disclosure is not limited thereto, and may be modified in a variety of ways.

In the foregoing embodiment, description has been given of a configuration in which the analog transistor including the amplification transistor is disposed in the second substrate; however, the present disclosure is not limited thereto, and is applicable to a configuration in which an analog transistor other than the amplification transistor is disposed in the second substrate, in place of the configuration.

It is to be noted that the effects described in the present specification are illustrative and non-limiting. The present disclosure may have effects other than those described in the present specification.

It is to be noted that the present technology may have the following configurations. In the following configurations according to the present technology, the sensor pixels are disposed in the first substrate and the analog transistor is disposed in the second substrate, which makes it possible to increase the occupied area of the analog transistor and reduce noise without decreasing the occupied area of the photodiode.

(1)

An imaging device provided with a stacking structure, the stacking structure including:

a first substrate including a sensor pixel that performs photoelectric conversion and outputs a signal charge;

a second substrate including a first signal processing circuit that is included in a readout circuit and includes a first analog transistor, the readout circuit that outputs a pixel signal on the basis of the signal charge; and

a third substrate including a logic circuit that performs processing on the pixel signal,

the first substrate, the second substrate, and the third substrate being stacked in order.

(2)

The imaging device according to (1), in which

the first substrate further includes a floating diffusion in which the signal charge is accumulated, and

the first analog transistor includes an amplification transistor including a gate electrode coupled to the floating diffusion.

(3)

The imaging device according to one or more (1) to (2), in which

the sensor pixel includes a plurality of sensor pixels, and

the readout circuit includes one analog-to-digital conversion circuit for each of the sensor pixels.

(4)

The imaging device according to one or more of (1) to (3), in which

the readout circuit includes an analog-to-digital conversion circuit including a comparison circuit, and

the first analog transistor is included in the comparison circuit.

(5)

The imaging device according to one or more of (1) or (4), in which

the sensor pixel includes a plurality of sensor pixels,

the sensor pixels are provided in rows and columns, and

the readout circuit includes one analog-to-digital conversion circuits for each of the columns of the sensor pixels.

(6)

The imaging device according to one or more of (1) to (5), in which

the readout circuit includes a vertical signal line, and

the first analog transistor includes a load transistor coupled to the vertical signal line.

(7)
The imaging device according to one or more of (1) to (6), in which
the readout circuit includes a sample-and-hold circuit,
the first analog transistor includes an input transistor included in the sample-and-hold circuit.
(8)
The imaging device according to one or more of (1) to (7), in which
the first analog transistor includes:
a channel formation region provided in a semiconductor region of the second substrate,
a gate insulation film provided on the channel formation region,
a gate electrode provided on the gate insulation film,
a source region provided at a position adjacent to the channel formation region in the semiconductor region of the second substrate,
a drain region provided at a position adjacent to the channel formation region on a side opposite to the source region as viewed from the channel formation region in the semi-conductor region of the second substrate,
a first metal silicide layer provided to cover a front surface of the gate electrode,
a second metal silicide layer provided to cover a front surface of the source region, and
a third metal silicide layer provided to cover a front surface of the drain region.
(9)
The imaging device according to one or more of (1) to (8), in which
the third substrate includes a second signal processing circuit that is included together with the first signal processing circuit in the readout circuit and includes a second analog transistor.
(10)
The imaging device according to one or more of (1) to (9), in which the first analog transistor includes an NMOS transistor.
(11)
The imaging device according to one or more of (1) to (9), in which the first analog transistor includes an NMOS transistor and a PMOS transistor.
(12)
The imaging device according to one or more of (1) to (11), in which the sensor pixels each include a photodiode and a transfer transistor.
(13)
The imaging device according to one or more of (1) to (12), in which the readout circuit includes one or more of an amplification transistor, a reset transistor, and a select transistor.
(14)
The imaging device according to one or more of (1) to (13), in which the readout circuit includes a portion of an analog-to-digital conversion circuit.
(15)
The imaging device according to one or more of (1) to (14), in which the logic circuit includes a portion of an analog-to-digital conversion circuit.
(16)
The imaging device according to one or more of (1) to (15), in which
the sensor pixel includes a plurality of sensor pixels, and
the first substrate includes the plurality of sensor pixels, and includes an element separator that separates the plurality of sensor pixels.
(17)
The imaging device according to one or more of (1) to (16), in which
the sensor pixel includes a plurality of sensor pixels,
the first substrate includes the plurality of sensor pixels, and
the readout circuit is electrically coupled to the plurality of sensor pixels.
(18)
The imaging device according to one or more of (1) to (17), in which
the sensor pixel includes a plurality of sensor pixels, and
the first substrate includes one floating diffusion for each of the sensor pixels.
(19)
The imaging device according to one or more of (1) to (17), in which
the sensor pixel includes a plurality of sensor pixels, and
the first substrate includes the plurality of sensor pixels, and includes one floating diffusion for the plurality of sensor pixels.
(20)
An electronic apparatus including:
an optical system;
an imaging device; and
a signal processing circuit,
the imaging device being provided with a stacking structure including a first substrate,
a second substrate, and a third substrate that are stacked in order,
the first substrate including a sensor pixel that performs photoelectric conversion and outputs a signal charge,
the second substrate including a first signal processing circuit that is included in a readout circuit and includes a first analog transistor, the readout circuit that outputs a pixel signal on the basis of the signal charge, and
the third substrate including a logic circuit that performs processing on the pixel signal.
(21)
An imaging device comprising:
a first substrate including at least one sensor portion that converts light into electric charge;
a second substrate including a first portion of a readout circuit including at least one first transistor, wherein the readout circuit outputs a pixel signal based on the electric charge; and
a third substrate including a logic circuit that performs processing on the pixel signal,
wherein the first substrate, the second substrate, and the third substrate are stacked in that order.
(22)
The imaging device according to (21), wherein
the first substrate further includes a floating diffusion that accumulates the electric charge, and
the at least one first transistor includes an amplification transistor including a gate electrode coupled to the floating diffusion.
(23)
The imaging device according to one or more of (21) to (22), wherein
the at least one sensor portion comprises a plurality of sensor portions, and
the readout circuit includes an analog-to-digital conversion circuit for each of the plurality of sensor portions.
(24)
The imaging device according to one or more of (21) to (23), wherein
the readout circuit includes a first part of an analog-to-digital conversion circuit including a comparison circuit, and
the at least one first transistor is included in the comparison circuit.
(25)
The imaging device according to one or more of (21) to (24), wherein
the at least one sensor portion comprises a plurality of sensor portions,
the plurality of sensor portions are provided in rows and columns, and
the readout circuit includes an analog-to-digital conversion circuit for each of the columns.
(26)
The imaging device according to one or more of (21) to (25), wherein
the readout circuit includes a vertical signal line, and
the at least one first transistor includes a load transistor coupled to the vertical signal line.
(27)
The imaging device according to one or more of (21) to (26), wherein
the readout circuit includes a sample-and-hold circuit,
the at least one first transistor includes an input transistor included in the sample-and-hold circuit.
(28)
The imaging device according to one or more of (21) to (27), wherein
the at least one first transistor includes:
a channel region provided in a semiconductor region of the second substrate,
a gate insulation film provided on the channel region,
a gate electrode provided on the gate insulation film,
a source region provided at a position adjacent to the channel region in the semi-conductor region of the second substrate,
a drain region provided in the semiconductor region of the second substrate at a position adjacent to the channel region on a side of the channel region opposite to the source region,
a first metal layer provided to cover a front surface of the gate electrode,
a second metal layer provided to cover a front surface of the source region, and
a third metal layer provided to cover a front surface of the drain region.
(29)
The imaging device according to one or more of (21) to (28), wherein
the third substrate includes a second portion of the readout circuit coupled to the first portion of the readout circuit, the second portion of the readout circuit including a second transistor.
(30)
The imaging device according to one or more of (21) to (29), wherein the at least one first transistor includes an NMOS transistor and/or a PMOS transistor, and wherein the at least one first transistor receives and outputs an analog signal based on the electric charge, and the second transistor receives and outputs a digital signal based on the analog signal.
(31)
The imaging device according to one or more of (21) to (30), wherein the at least one sensor portion includes a plurality of sensor portions that share the at least one first transistor.
(32)
The imaging device according to one or more of (21) to (31), wherein the at least one sensor portion includes a photodiode and a transfer transistor.
(33)
The imaging device according to one or more of (21) to (32), wherein the readout circuit includes one or more of an amplification transistor, a reset transistor, and a select transistor.
(34)
The imaging device according to one or more of (21) to (33), wherein the first portion of the readout circuit includes a first portion of an analog-to-digital conversion circuit, and the logic circuit includes a second portion of the analog-to-digital conversion circuit, and wherein the first portion of the analog-to-digital conversion circuit receives an analog signal based on the electric charge, and the second portion of the analog-to-digital conversion circuit outputs a digital signal based on the analog signal.
(35)
The imaging device according to one or more of (21) to (34), wherein the at least one sensor portion includes a plurality of sensor portions that share the first portion and the second portion of the analog-to-digital conversion circuit.
(36)
The imaging device according to one or more of (21) to (35), wherein the at least one sensor portion comprises a plurality of sensor portions, and the first substrate includes the plurality of sensor portions, and includes an isolation region that separates the plurality of sensor portions.
(37)
The imaging device according to one or more of (21) to (36), wherein the at least one sensor portion includes a plurality of sensor portions, the first substrate includes the plurality of sensor portions, and the readout circuit is electrically coupled to the plurality of sensor portions.
(38)
The imaging device according to one or more of (21) to (37), wherein the at least one sensor portion comprises a plurality of sensor portions, and the first substrate includes a floating diffusion for each of the plurality of sensor portions.
(39)
The imaging device according to one or more of (21) to (38), wherein
the at least one sensor portion comprises a plurality of sensor portions, and
the first substrate includes the plurality of sensor portions, and includes a floating diffusion shared by the plurality of sensor portions.
(40)
An electronic apparatus comprising:
an optical system;
an imaging device; and
a signal processing circuit,
the imaging device including:
a first substrate including at least one sensor portion that converts light into electric charge;
a second substrate including a first portion of a readout circuit and including at least one first transistor, wherein the readout circuit outputs a pixel signal based on the electric charge; and
a third substrate including a logic circuit that performs processing on the pixel signal, wherein the first substrate, the second substrate, and the third substrate are stacked in that order.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 imaging device

10 first substrate

11 semiconductor substrate

12 sensor pixel

13 pixel region

20 second substrate

21 semiconductor substrate

22 readout circuit

22A first signal processing circuit

22B second signal processing circuit

23 pixel drive line

24 vertical signal line

24A signal readout line

30 third substrate

31 semiconductor substrate

32 logic circuit

33 vertical drive circuit

34 signal processing circuit

35 horizontal drive circuit

36 system control circuit

PD photodiode

TX transfer transistor

FD floating diffusion

AMP amplification transistor

REF reference signal input transistor

Vb current source transistor

PTR1, PTR2 transistor

RST reset transistor

SEL select transistor

What is claimed is:

1. An imaging device comprising:
a first substrate including at least one sensor portion that converts light into electric charge;
a second substrate including a first portion of a readout circuit having at least one first transistor, wherein the readout circuit outputs a pixel signal based on the electric charge; and
a third substrate including a logic circuit that performs processing on the pixel signal,
wherein the first substrate, the second substrate, and the third substrate are stacked in that order.

2. The imaging device according to claim 1, wherein
the first substrate further includes a floating diffusion that accumulates the electric charge, and
the at least one first transistor includes an amplification transistor including a gate electrode coupled to the floating diffusion.

3. The imaging device according to claim 1, wherein
the at least one sensor portion comprises a plurality of sensor portions, and
the readout circuit includes an analog-to-digital conversion circuit for each of the plurality of sensor portions.

4. The imaging device according to claim 1, wherein
the readout circuit includes a first part of an analog-to-digital conversion circuit including a comparison circuit, and
the at least one first transistor is included in the comparison circuit.

5. The imaging device according to claim 1, wherein
the at least one sensor portion comprises a plurality of sensor portions,
the plurality of sensor portions are provided in rows and columns, and
the readout circuit includes an analog-to-digital conversion circuit for each of the columns.

6. The imaging device according to claim 5, wherein
the readout circuit includes a vertical signal line, and
the at least one first transistor includes a load transistor coupled to the vertical signal line.

7. The imaging device according to claim 5, wherein
the readout circuit includes a sample-and-hold circuit,
the at least one first transistor includes an input transistor included in the sample-and-hold circuit.

8. The imaging device according to claim 1, wherein
the at least one first transistor includes:
a channel region provided in a semiconductor region of the second substrate,
a gate insulation film provided on the channel region,
a gate electrode provided on the gate insulation film,
a source region provided at a position adjacent to the channel region in the semiconductor region of the second substrate,
a drain region provided in the semiconductor region of the second substrate at a position adjacent to the channel region on a side of the channel region opposite to the source region,
a first metal layer provided to cover a front surface of the gate electrode,
a second metal layer provided to cover a front surface of the source region, and
a third metal layer provided to cover a front surface of the drain region.

9. The imaging device according to claim 1, wherein
the third substrate includes a second portion of the readout circuit coupled to the first portion of the readout circuit, the second portion of the readout circuit including a second transistor.

10. The imaging device according to claim 1, wherein the at least one first transistor includes an NMOS transistor and/or a PMOS transistor, and wherein the at least one first transistor receives and outputs an analog signal based on the electric charge, and the second transistor receives and outputs a digital signal based on the analog signal.

11. The imaging device according to claim 9, wherein the at least one sensor portion includes a plurality of sensor portions that share the at least one first transistor.

12. The imaging device according to claim 1, wherein the at least one sensor portion includes a photodiode and a transfer transistor.

13. The imaging device according to claim 1, wherein the readout circuit includes one or more of an amplification transistor, a reset transistor, and a select transistor.

14. The imaging device according to claim 1, wherein the first portion of the readout circuit includes a first portion of an analog-to-digital conversion circuit, and the logic circuit includes a second portion of the analog-to-digital conversion circuit, and wherein the first portion of the analog-to-digital conversion circuit receives an analog signal based on the electric charge, and the second portion of the analog-to-digital conversion circuit outputs a digital signal based on the analog signal.

15. The imaging device according to claim 14, wherein the at least one sensor portion includes a plurality of sensor portions that share the first portion and the second portion of the analog-to-digital conversion circuit.

16. The imaging device according to claim 1, wherein
the at least one sensor portion comprises a plurality of sensor portions, and
the first substrate includes the plurality of sensor portions, and includes an isolation region that separates the plurality of sensor portions.

17. The imaging device according to claim 1, wherein
the at least one sensor portion includes a plurality of sensor portions,
the first substrate includes the plurality of sensor portions, and
the readout circuit is electrically coupled to the plurality of sensor portions.

18. The imaging device according to claim 1, wherein
the at least one sensor portion comprises a plurality of sensor portions, and
the first substrate includes a floating diffusion for each of the plurality of sensor portions.

19. The imaging device according to claim 1, wherein
the at least one sensor portion comprises a plurality of sensor portions, and
the first substrate includes the plurality of sensor portions, and includes a floating diffusion shared by the plurality of sensor portions.

20. An electronic apparatus comprising:
an optical system;
an imaging device; and
a signal processing circuit,
the imaging device including:
a first substrate including at least one sensor portion that converts light into electric charge;
a second substrate including a first portion of a readout circuit having at least one first transistor, wherein the readout circuit outputs a pixel signal based on the electric charge; and
a third substrate including a logic circuit that performs processing on the pixel signal,
wherein the first substrate, the second substrate, and the third substrate are stacked in that order.
